(19) United States
(12) Patent Application Publication
(10) Pub. No.: US 2025/0236693 A1
(43) Pub. Date: Jul. 24, 2025

(54) RESIN COMPOSITION, AND MOLDED PRODUCT, CURED PRODUCT, FILM, COMPOSITE MATERIAL, CURED COMPOSITE MATERIAL, LAMINATE, METAL FOIL WITH RESIN, AND VARNISH FOR CIRCUIT BOARD MATERIAL OBTAINEDTHEREFROM

(71) Applicant: NIPPON STEEL CHEMICAL & MATERIAL CO., LTD., Tokyo (JP)

(72) Inventors: Masanao Kawabe, Tokyo (JP); Tadashi Kuratomi, Tokyo (JP)

(73) Assignee: NIPPON STEEL CHEMICAL & MATERIAL CO., LTD., Tokyo (JP)

(21) Appl. No.: 18/720,708

(22) PCT Filed: Jan. 30, 2023
(86) PCT No.: PCT/JP2023/002872

§ 371 Date: Jun. 17, 2024

(30) Foreign Application Priority Data
Jan. 31, 2022 (JP) 2022-013654

(51) Int. Cl. C08F 212/08; C08F 212/12; C08F 212/36; C08F 236/08; C08G 65/48; C08L 53/02

(52) U.S. Cl. CPC C08F 212/08; C08F 212/12; C08F 212/36; C08F 236/08; C08G 65/485; C08L 53/025; C08L 2203/16; C08L 2203/20; C08L 2205/03

(57) ABSTRACT

To provide a resin composition which exhibits excellent dielectric characteristics and bonding after being cured and which can be used as a dielectric material, an insulating material, and an adhesive material in the fields of electrical and electronic industries, spacecraft and aircraft industries. A resin composition containing: (A) a functional group-modified vinylaromatic copolymer containing a structural unit (a) derived from a divinylaromatic compound and a structural unit (b) derived from a monovinylaromatic compound, wherein 95% by mol or more of the structural unit (a) is a crosslinked structural unit (a1) represented by the following formula (1):

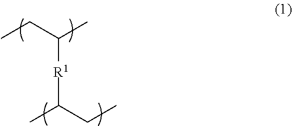

wherein R1 represents an aromatic hydrocarbon group having 6 to 30 carbon atoms; the functional group-modified vinylaromatic copolymer is modified by at least one functional group selected from the group consisting of an amino group, an alkoxysilyl group, and a hydroxyl group; and (B) a curable reactive resin and/or (C) a thermoplastic resin.

### TECHNICAL FIELD

The present invention relates to a resin composition including a modified vinylaromatic copolymer, a curable reactive resin, and/or a thermoplastic resin, and to a molded product, a cured product, a film, a composite material, a cured composite material, a laminate, a resin-coated metal foil, a varnish for a circuit board material, and the like obtained therefrom.

### BACKGROUND ART

Miniaturization and densification of a packaging method in a field of electronic devices for communication, consumer use, industrial use, and the like have become significant in recent years, and excellent heat resistance, dimensional stability, and electrical characteristics are required for materials. For example, a printed wiring board conventionally employs a copper clad laminate formed of a thermosetting resin such as a phenol resin or an epoxy resin as a material.

With recent miniaturization and achievement of higher function of electronic devices, substrate materials, which are thin and lightweight and also capable of achieving higher density wiring, are required for printed circuit boards. Furthermore, in recent years, computers and information device terminals have been increasingly using higher frequency signals to process a large amount of data at high speeds, but the higher the frequency, the greater the transmission loss of electrical signals. There is a strong need for the development of printed circuit boards compatible with higher frequencies. The transmission loss in a high-frequency circuit is greatly affected by the dielectric loss determined by the dielectric characteristics of the insulating layer (dielectric) around the wire, and a low dielectric constant and a low loss tangent (tan δ) of the printed circuit board substrate (especially, the insulating resin) are required. For example, in mobile communication-related devices, a substrate with a low dielectric loss tangent is strongly desired to reduce transmission loss in the microwave band above 5 GHz as signals become higher in frequency.

Furthermore, computers and other electronic information devices are now equipped with high-speed microprocessors with operating frequencies exceeding 350 MHZ, and the delay of high-speed pulse signals on printed circuit boards has become a problem. Since the delay time of a signal increases in proportion to the square root of the relative dielectric constant εr of an insulator around a wiring in a printed circuit board, a printed circuit board with a low dielectric constant is required for high-speed computers and the like.

In response to the above-mentioned technological trends in printed circuit boards, phenol resins and epoxy resins, which have been widely used before, have various well-balanced performances such as heat resistance, dimensional stability, and bonding, but have a disadvantage of high dielectric constant and loss tangent in a high-frequency band.

Cyanate ester resins have improved to some extent in performance such as heat resistance and dielectric characteristics, as compared to conventionally cured epoxy resins, but are insufficient in dielectric characteristics required for recent high-frequency compatible printed wiring boards. Moreover, the cyanate ester resins are usually solid or semi-solid at room temperature with low solubility, thus having a disadvantage of requiring a large amount of solvents to prepare the curable resin composition.

In addition, bismaleimide resins, which have excellent retention of physical properties at high temperature and high humidity and good electrical characteristics over a wide temperature range, are also widely used in the fields of advanced composite and electronics-related materials. However, the bismaleimide resins also have insufficient dielectric characteristics as insulating resin materials to be used for high-frequency compatible printed wiring boards, which require high-level low dielectric characteristics. Furthermore, the bismaleimide resins have the disadvantages of brittleness, low chemical resistance in the presence of base compounds, and low solubility, usually being solid or semi-solid at room temperature.

As a new material for solving the above-mentioned problem, Patent Literatures 1 to 3 discloses a resin composition containing a polyphenylene ether resin containing vinylbenzyl groups at both terminals. Although the curable resin has an excellent balance between heat resistance and dielectric characteristics, the resulting cured product has a disadvantage of a poor balance between dielectric characteristics and bonding.

Patent Literatures 4 to 6 disclose a soluble polyfunctional vinylaromatic copolymer synthesized from divinyl aromatic compounds and a curable resin composition containing this copolymer. The curable resin composition has better dielectric characteristics than the above-mentioned polyphenylene ether resin containing vinylbenzyl groups at both terminals but exhibits poor bonding.

Patent Literature 7 discloses a resin composition containing (A) a thermosetting resin with a molecular weight of 800 to 1500 having a styrene group at the terminal, (B) a liquid epoxy resin, (C) a styrene-based thermoplastic elastomer, (D) a filling material, and (E) a curing agent. However, the dielectric characteristics and bonding of the resin composition are also insufficient as an adhesive material in fields where advanced characteristics are required.

Patent Literature 8 discloses a soluble polyfunctional vinylaromatic copolymer obtained by copolymerizing a divinylaromatic compound with a monovinylaromatic compound and having a chain hydrocarbon group or an aromatic hydrocarbon group via an ether bond or a thioether bond at a part of the terminal group. However, the soluble polyfunctional vinyl aromatic copolymer also has a poor balance between dielectric characteristics and bonding.

### CITATION LIST

### Patent Literature

Patent Literature 1: JP2016-191073 A
Patent Literature 2: JP2016-28885 A
Patent Literature 3: JP2015-86330 A
Patent Literature 4: WO2018/181842 A
Patent Literature 5: WO2017/115813 A
Patent Literature 6: JP2018-39995 A
Patent Literature 7: JP2016-147945 A
Patent Literature 8: JP2007-332273 A

### SUMMARY OF INVENTION

An object of the present invention is to provide a resin composition which exhibits excellent dielectric characteristics and bonding after being cured and which can be used as a dielectric material, an insulating material, and an adhesive material in the fields of electrical and electronic industries, spacecraft and aircraft industries, and the like. Another object is to provide a film obtained from a curable resin composition, a cured product of the film, a curable composite material, a cured product of the material, a laminate, a resin-coated copper foil, and the like.

The present applicant has made intensive studies in view of the above problems, and as a result, has found that the above problems can be solved by a material with an excellent balance of characteristics, such as dielectric characteristics and bonding by containing (A) a specified polyfunctional vinylaromatic copolymer having a branched structure simultaneously with interaction functions with different materials as an essential constituent of a resin composition, as well as (B) a curable reactive resin, and/or (C) a thermoplastic resin, leading to completion of the present invention.

The present invention is a resin composition containing:
(A) a functional group-modified vinylaromatic copolymer containing a structural unit (a) derived from a divinylaromatic compound and a structural unit (b) derived from a monovinylaromatic compound, wherein 95% by mol or more of the structural unit (a) is a crosslinked structural unit (al) represented by the following formula (1):

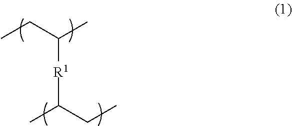

wherein R¹ represents an aromatic hydrocarbon group having 6 to 30 carbon atoms;
the functional group-modified vinylaromatic copolymer is modified by at least one functional group selected from the group consisting of an amino group, an alkoxysilyl group, and a hydroxyl group, the average number of functional groups per molecule is 1.5 or more, and a number average molecular weight Mn is 500 to 30,000; and
(B) a curable reactive resin and/or (C) a thermoplastic resin,
wherein each of components (A), (B) and (C) is blended in a proportion that satisfies the following numerical expressions (1) to (3):

$$( A ) + ( B ) + ( C ) = 100 ( wt \% ) \qquad ( 1 )$$

$$( A ) = 0.1 to 50 ( wt \% ) \qquad ( 2 )$$

$$( B ) + ( C ) = 50 to 99.9 ( wt \% ) \qquad ( 3 )$$

The above-mentioned resin composition of the present invention can further contain (D) a curing catalyst.

Furthermore, the component (A) in the resin composition of the present invention can also be a functional-group modified vinylaromatic copolymer containing structural units (c) derived from conjugated diene compound.

In the resin composition of the present invention, a thermosetting resin containing one or more functional groups selected from the group consisting of an epoxy group, a cyanate group, a vinyl group, an ethynyl group, an isocyanate group, and a hydroxyl group can be used as the component (B).

In the resin composition of the present invention, a homopolymer or copolymer of a monomer including 50 to 100% by mol of one or more monomers selected from butadiene, isoprene, styrene, ethylstyrene, divinylbenzene, N-vinylphenylmaleimide, acrylic ester and acrylonitrile can be used as the component (C). At least one or more thermoplastic resins selected from the group consisting of optionally substituted polyphenylene oxide, polyolefin having a ring structure, polysiloxane, polyester, polysulfone, polyethersulfone, polyamide, polyimide, polyamideimide, and polyetherimide can also be used as the component (C).

The resin composition of the present invention can further contain (E) a flame retardant and/or (F) a filling agent.

The present invention is also a molded product obtained by molding the above resin composition.

The present invention is also a cured product obtained by curing the above resin composition.

The present invention is also a film containing the above resin composition.

The present invention is also a composite material consisting of the above resin composition and a base material, wherein a proportion of the base material contained is 5 to 90% by weight.

The present invention is also a cured composite material obtained by curing the above composite material.

The present invention is also a laminate having a layer of the above cured composite material and a metal foil layer.

The present invention is also a resin-coated metal foil having a film of the above resin composition on one side of a metal foil.

The present invention is also a varnish for a circuit board material obtained by dissolving the above resin composition in an organic solvent.

The resin composition of the present invention can be processed into a film, a sheet, or a prepreg, in addition to having excellent bonding with different materials, dielectric characteristics, and heat resistance.

### DESCRIPTION OF EMBODIMENTS

In the resin composition of the present invention, the functional group-modified vinylaromatic copolymer as the component (A) is a copolymer containing a structural unit (a) derived from a divinylaromatic compound and a structural unit (b) derived from a monovinylaromatic compound, wherein 95% by mol or more of the structural unit (a) is a crosslinked structural unit (al) represented by the above structural formula (1), and is modified by at least one functional group selected from the group consisting of an amino group, an alkoxysilyl group, and a hydroxyl group.

The structural unit (a) derived from a divinylaromatic compound, contained in the functional group-modified vinylaromatic copolymer (A) plays a significant role as a crosslinking component that causes the copolymer to branch and makes it polyfunctional. When polymers of the conjugated diene compound are modified using the polyfunctional modified vinylaromatic copolymer, a multi-branched component of high molecular weight is generated, allowing enhancement in wear resistance.

Examples of the divinylaromatic compounds to be used preferably include divinylbenzene (including each isomer), divinylnaphthalene (including each isomer), and divinylbiphenyl (including each isomer), but are not limited thereto. These may be used alone or two or more kinds thereof may be used in combination. The divinylaromatic compound is more preferably divinylbenzene (m-isomer, p-isomer, or an isomer mixture thereof) from the viewpoint of fabricability.

The structural unit (b) derived from a monovinylaromatic compound, contained in the functional group-modified vinylaromatic copolymer (A), improves solvent solubility, compatibility, and processability of the copolymer.

Examples of the monovinylaromatic compounds include vinylaromatic compounds such as styrene, vinylnaphthalene, vinylbiphenyl, and α-methylstyrene; nuclear alkyl-substituted vinylaromatic compounds such as o-methylstyrene, m-methylstyrene, p-methylstyrene, o, p-dimethylstyrene, o-ethylvinylbenzene, m-ethylvinylbenzene, and p-ethylvinylbenzene; and cyclic vinylaromatic compounds such as indene, acenaphthylene, benzothiophene, and coumarone, but are not limited thereto.

To prevent gelation of the copolymer and to improve solubility in the solvent, compatibility, and processability, styrene, ethylvinylbenzene (including each isomer), ethylvinylbiphenyl (including each isomer), ethylvinylnaphthalene (including each isomer), and indene are particularly preferably used from the viewpoint of cost and ease of availability. The monovinylaromatic compound is more preferably styrene, ethylvinylbenzene (m-isomer, p-isomer, or an isomer mixture thereof), or indene from the viewpoint of compatibility and cost.

The functional group-modified vinylaromatic copolymer (A) can also contain a structural unit (c) derived from a conjugated diene compound, which has an effect of increasing the introduction efficiency of a modification group to be introduced into the modified vinylaromatic copolymer.

The conjugated diene compound is preferably a conjugated diene compound having 4 to 12 carbon atoms per molecule, more preferably a conjugated diene compound having 4 to 8 carbon atoms per molecule. Examples of such a conjugated diene compound include, but are not limited to, 1,3-butadiene, isoprene, 2,3-dimethyl-1,3-butadiene, 1,3-pentadiene, 3-methyl-1,3-pentadiene, 1,3-hexadiene, and 1,3-heptadiene. These may be used singly or in combinations of two or more.

Among these, 1,3-butadiene and isoprene are preferable from the viewpoint of ease of a copolymerization reaction with the aromatic vinyl compound, and ease of industrial availability.

The functional group-modified vinylaromatic copolymer (A) is modified by a polymerization initiator or modifying agent having at least one functional group selected from the group consisting of an amino group, an alkoxysilyl group and a hydroxyl group, and the amount of introduction of the modifying agent is 1.5 or more in terms of the average number of functional groups per molecule. A value of 1.5 or more, obtained by dividing the number average molecular weight of the copolymer by the equivalent of functional group, can be determined to mean formation of 1.5 or more functional groups. The amount of introduction of the polymerization initiator or modifying agent having functional group(s) is preferably 1.5 to 20, more preferably 1.5 to 5.0 in terms of the average number of functional groups per molecule, and is further preferably 1.5 to 4.0.

Preferably, 10% by mol or more of at least one functional group selected from the group consisting of an amino group, an alkoxysilyl group, and a hydroxyl group is an alkoxysilyl group. Of the functional groups, the alkoxysilyl group is more preferably 30% by mol or more, and further preferably 50% by mol or more.

The functional group-modified vinylaromatic copolymer (A) can be produced by the following anionic polymerization method.

In other words, the production method includes a polymerization step of copolymerizing the divinylaromatic compound with the monovinylaromatic compound, or if desired, the divinylaromatic compound and the monovinylaromatic compound with a monomer anionically copolymerizable with these compounds, by use of an alkali metal compound or an alkaline earth metal compound as an anionic polymerization initiator, in particular, a compound which is further blended with a conjugated diene compound to obtain a vinylaromatic copolymer (M) having a branched structure and an active terminal; and a terminal modification step of forming the functional group at the active terminal of the vinylaromatic copolymer (M).

The functional group-modified vinylaromatic copolymer (A) is a copolymer containing a structural unit (a) derived from a divinylaromatic compound and a structural unit (b) derived from a monovinylaromatic compound as essential structural units. The structural unit (c) derived from a conjugated diene compound may be an essential structural unit. However, another monomer having anionic polymerizability, such as a trivinylaromatic compound, can be used, and a structural unit (d) derived from the other monomer can be introduced into the copolymer within a range that does not impair the effects of the present invention.

Specific examples of the other monomers preferably include 1,3,5-trivinylbenzene and 1,3,5-trivinylnaphthalene, but are not limited thereto. These can be used alone, or two or more kinds thereof may be used in combination.

The other monomers may be used within a range of less than 30% by mol of all monomers. Therefore, the amount of the structural unit (d) derived from other monomers is within a range of less than 30% by mol based on the total amount of the structural units in the copolymer.

The functional group-modified vinylaromatic copolymer (A) includes at least a part of the structural unit (a) as the crosslinked structural unit (a1) represented by the above structural formula (1). A molar fraction (also referred to as “degree of crosslinking”) indicating the proportion of the crosslinked structural unit (al), based on the total amount of the structural unit (a), is 0.95 or more.

The degree of crosslinking of the crosslinked structural unit (a1) is preferably 0.98 or more and more preferably 0.99 or more.

The degree of crosslinking is a parameter that can be controlled and changed as desired. However, when the degree of crosslinking is less than 0.95, many highly reactive pendant vinyl groups remain in the functional-group modified vinylaromatic copolymer (A) to result in a tendency to easily cause a crosslinking reaction to occur in a molecule having the pendant vinyl group remaining in the copolymer as a starting point, leading to a tendency to generate a microgel in compounding and vulcanization due to the thermal history or the like in the subsequent steps.

The polymerization method of the functional group-modified vinylaromatic copolymer (A) includes a polymerization step and a terminal modification step as described above.

A polymerization initiator composed of an alkali metal compound or an alkaline earth metal compound used in the polymerization process is described.

The alkali metal compound used as a polymerization initiator is not particularly limited, and for example, an organolithium compound is preferable. The organolithium compound may be either a low molecular weight organolithium compound or a solubilized oligomeric organolithium compound. Examples thereof include compounds having a carbon-lithium bond, compounds having a nitrogen-lithium bond, and compounds having a tin-lithium bond in the bonding mode of organic groups and lithium. The use of the organolithium compound provides good initiation efficiency and a good living rate of the polymer. Examples of the organolithium compounds include, but are not particularly limited to, organomonolithium compounds, organodilithium compounds, and organopolylithium compounds. A hydrocarbon containing the functional groups is suitable as an organic group, which has the advantage of excellent solubility in an organic solvent and further has an excellent initiation rate. A modification group containing a functional group can also be imparted to the starting terminal by the use of the compounds having a nitrogen-lithium bond and the compounds having a tin-lithium bond.

Examples of other organoalkali metal compounds include, but are not particularly limited to, organosodium compounds, organopotassium compounds, organorubidium compounds, and organocesium compounds. More specific examples thereof include sodium naphthalene and potassium naphthalene. Other examples thereof include alkoxides such as lithium, sodium and potassium, sulfonates, carbonates, and amides. Such organoalkali metal compounds may also be used in combination with other organometallic compounds.

Examples of the alkaline earth metal compound used as a polymerization initiator include organomagnesium compounds, organocalcium compounds, and organostrontium compounds. Compounds of alkaline earth metals such as alkoxides, sulfonates, carbonates, and amides may also be used. These organoalkaline earth metal compounds may be used in combination with the alkali metal compounds or the other organometallic compounds.

The terminal structural unit of the functional group-modified vinylaromatic copolymer (A) can be modified by using a polymerization initiator having at least one functional group selected from the group consisting of an amino group, an alkoxysilyl group, and a hydroxyl group.

Examples of alkali metal compounds as a polymerization initiator having a functional group include, but are not particularly limited to, lithiumamide compounds to be obtained by lithiation of hydrogen in a secondary amine and alkyllithium to which the functional group is bonded. The functional group can be imparted to the polymerization initiation terminal of the conjugated diene-based copolymer by these compounds.

The functional group is not particularly limited, but preferably a functional group that is inert to alkali metals, such as a disubstituted amino group, i.e., tertiary amine. Examples of the protected monosubstituted amino group or the protected amino group include those in which one hydrogen of the monosubstituted amino group or two hydrogens of the amino group are each substituted with a trialkylsilyl group.

Examples of the organolithium compounds used as polymerization initiators include, but are not particularly limited to, mono-organolithium compounds such as n-butyllithium, sec-butyllithium, tert-butyllithium, n-propyllithium, iso-propyllithium, and benzyllithium; and polyfunctional organolithium compounds such as 1,4-dilithiobutane, 1,5-dilithiopentane, 1,6-dilithiohexane, 1,10-dilithiodecane, 1,1-dilithiodiphenylene, dilithiopolybutadiene, dilithiopolyisoprene, 1,4-dilithiobenzene, 1,2-dilithio-1,2-diphenylethane, 1,4-dilithio-2-ethylcyclohexane, 1,3,5-trilithiobenzene, and 1,3,5-trilithio-2,4,6-triethylbenzene. Among these, mono-organolithium compounds such as n-butyllithium, sec-butyllithium, and tert-butyllithium are preferable.

As the polymerization initiator having a functional group, the organolithium compound is not particularly limited, and examples thereof include the following compounds. The types of functional groups that can be imparted to the polymer are described in parentheses.

Examples thereof include dipropylaminolithium, diisopropylaminolithium, dibutylaminolithium, tetramethyleniminolithium, pentamethyleniminolithium, hexamethyleniminolithium, heptamethyleniminolithium, 2-dimethylaminoethyllithium, 3-dimethylaminopropyllithium, 3-diethylaminopropyllithium, and 4-dimethylaminobutyllithium (these are disubstituted amino groups); 2-trimethylsilylethylaminoethyllithium and 3-trimethylsilylmethylaminopropyllithium (these are monosubstituted amino groups); and 2-bistrimethylsilylaminoethyllithium and 3-bistrimethylsilylaminopropyllithium (these are amino groups).

As the polymerization initiator, oligomeric initiators in which various lithium-based initiators react with monomers may be used. As the monomer, a monomer having at least one functional group selected from the group consisting of amino groups, alkoxysilyl groups, and hydroxyl groups can be used.

The oligomeric initiators are preferably those with a molecular weight of 1,000 or less for easy industrial handling.

Examples of the polyfunctional initiators include, but are not particularly limited to, organodilithium compounds and organopolylithium compounds. The organic groups are not particularly limited, and hydrocarbons are suitable. This has the advantage of excellent solubility in an organic solvent and further has an excellent initiation rate.

Examples of methods for preparing polyfunctional initiators include, but are not particularly limited to, methods involving the reaction of metallic lithium dispersion with a polyhalogenated hydrocarbon compound.

In the polymerization step, polar compounds may be added. The addition of the polar compounds is involved in an initiation reaction and a growth reaction, and is also effective in controlling the molecular weight and molecular weight distribution, promoting the polymerization reaction, or the like.

Examples of the polar compounds include ethers such as tetrahydrofuran, diethyl ether, dioxane, ethylene glycol dimethyl ether, ethylene glycol dibutyl ether, diethylene glycol dimethyl ether, diethylene glycol dibutyl ether, dimethoxybenzene, and 2,2-bis(2-oxolanyl)propane; tertiary amine compounds such as tetramethylethylenediamine, dipiperidinoethane, trimethylamine, triethylamine, pyridine, and quinuclidine; alkali metal alkoxide compounds such as potassium-tert-amylate, potassium-tert-butylate, sodium-tert-butylate, and sodium amylate; and phosphine compounds such as triphenylphosphine. These polar compounds may be used alone, or two or more kinds thereof may be in combination.

The amount of the polar compound used is not particularly limited, and can be selected depending on the purpose and the like. Generally, the amount used is preferably 0.01 to 100 mol based on 1 mol of the polymerization initiator or the polyfunctional initiator. Such a polar compound can be used as a regulator for an initiation reaction and a growth reaction of the modified vinylaromatic copolymer (A) in an appropriate amount depending on the desired molecular weight and molecular weight distribution. Many polar compounds simultaneously have an effective randomization effect in the copolymerization of a divinylaromatic compound with a monovinylaromatic compound, and can be used to adjust the distribution of the aromatic vinyl compound and as an adjuster for the styrene block amount.

The copolymerization of the divinylaromatic compound with a monomer containing the monovinylaromatic compound is preferably performed by solution polymerization in an inert solvent. The polymerization solvent is not particularly limited, and for example, hydrocarbon solvents such as saturated hydrocarbon and aromatic hydrocarbon are used. Specific examples thereof include aliphatic hydrocarbons such as butane, pentane, hexane, and heptane; alicyclic hydrocarbons such as cyclopentane, cyclohexane, methylcyclopentane, methylcyclohexane, dimethylcyclohexane, ethylcyclohexane, and decalin; aromatic hydrocarbons such as benzene, toluene, and xylene; and hydrocarbon-based solvents composed of mixtures thereof.

The monomers and polymerization solvents are each preferably treated alone or a mixed solution thereof using an organometallic compound. Thereby, the divinylaromatic compound, the monomer such as monovinylaromatic compound, and allenes and acetylenes contained in the polymerization solvent can be treated. As a result, a polymer having an active terminal in high concentration can be obtained, allowing a high modification rate to be achieved.

The polymerization temperature in copolymerization is not particularly limited as long as it is a temperature at which a living anionic polymerization progresses, but is preferably 0° C. or higher from the viewpoint of the productivity, and preferably 120° C. or lower from the viewpoint of sufficiently securing the reaction amount to the active terminal in the terminal modification step after the completion of the polymerization. The polymerization temperature is more preferably 50 to 100° C.

The mode of the polymerization reaction is not particularly limited, but the reaction can be performed in a polymerization mode such as a batch process (also referred to as a “batch type”) or a continuous process. In the continuous process, one reactor or two or more series of reactors can be used. The reactor to be used is a tank type equipped with a stirrer, a tube type, or the like. In the batch process, the molecular weight distribution of the polymer to be obtained is generally narrow and tends to be 1.0 or more and less than 1.8 in terms of Mw/Mn. In the continuous process, the molecular weight distribution of the polymer to be obtained is generally wide and tends to be 1.8 or more and 3 or less in terms of Mw/Mn.

In the polymerization method of the functional group-modified vinylaromatic copolymer (A), after obtaining a vinylaromatic copolymer having a branched structure and an active terminal in the polymerization step, this active terminal is subjected to a step of reacting a compound (containing a precursor, also referred to as “modifying agent”) having at least one functional group selected from the group consisting of an amino group, an alkoxysilyl group, and a hydroxyl group. The modifying agent may also be a polymerization initiator for forming a functional group in the polymerization step. A functional group is introduced into the copolymer by such a polymerization initiator or modifying agent.

The reaction temperature, the reaction time, and the like in a reaction of the compound (including a precursor) having the functional group with the active terminal are not particularly limited, but the reaction is preferably performed at 0 to 120° C. for 30 seconds or longer.

The amount of such polymerization initiator and modifying agent having functional group(s), here added, is not particularly limited, and the total number of moles of the modifying agent having functional group(s) is preferably in a range from 0.05 to 6 times relative to the number of equivalent of an active species (active terminal equivalent) derived from the polymerization initiator. A more preferable lower limit is 0.3, further preferably 0.5, and particularly preferably 0.7. On the contrary, a more preferable upper limit is 3 times, further preferably 2 times, and particularly preferably 1.5 times. The amount added is preferably 0.05 times or more from the viewpoint of obtaining a sufficient modification ratio in the target modified vinylaromatic copolymer.

In the active terminal modification step, if the polymerization step is a batch process, the modification reaction may be performed continuously in the same reactor used in the polymerization step or may be performed by transferring the product to the next reactor. If the polymerization step is a continuous process, the reaction is performed by transferring the product to the next reactor. The active terminal modification step is preferably performed immediately after the polymerization step, and the reaction is preferably performed by mixing the modifying agent within 5 minutes. The reactors for the modification reaction are preferably those in which stirring is sufficiently performed. Specifically, the reactors are static mixer type reactors, tank type reactors equipped with stirrers, or the like.

The active terminal modification step is a step in which the vinylaromatic copolymer is modified by reacting the modifying agent having at least one functional group selected from an amino group, an alkoxysilyl group, and a hydroxyl group with the active terminal of the vinylaromatic copolymer obtained in the preceding polymerization step. The modifying agent essentially has an amino group, an alkoxysilyl group or a hydroxyl group as a functional group, and may have any other functional group, for example, a halogen group, a ketone group, an ester group, an amide group, and/or an epoxy group as long as the effects of the present invention are not impaired.

Specific examples of the modifying agent having an amino group include, but are not particularly limited to, compounds having a functional group binding to an amino group and a polymeric active terminal in the molecule, preferably without active hydrogen. The amino group is not particularly limited, and specifically functional groups that are inert to alkali metals, such as a disubstituted amino group, i.e., a tertiary amine, a protected monosubstituted amino group, and an amino group with two hydrogens protected are preferable. Examples of the protected monosubstituted amino group or the amino group with two hydrogens protected include those in which one hydrogen of the monosubstituted amino group or two hydrogens of the amino group are each substituted with a trialkylsilyl group.

Specific examples of the modifying agent having an alkoxysilyl group include, but are not particularly limited to, compounds having a plurality of alkoxysilyl groups in the molecule (including compounds having a silyl group to which a plurality of alkoxy groups are bonded) and compounds having a functional group that binds to the alkoxysilyl group and the polymeric active terminal in the molecule. These are preferably compounds without active hydrogen.

Specific examples of the modifying agent forming a hydroxyl group include, but are not particularly limited to, compounds having a functional group that binds to the polymeric active terminal and in which a hydroxyl group is generated after the binding reaction, and compounds having a functional group that does not bind to the polymeric active terminal and in which a hydroxyl group is generated later by hydrolysis or other reactions, and the compounds without active hydrogen are preferable.

Examples of the compounds having a functional group in which a hydroxyl group is generated after the binding reaction include compounds having a ketone group, an ester group, an amide group, and an epoxy group. Examples of the compounds having a functional group in which a hydroxyl group is generated by hydrolysis or other reactions after the binding reaction include compounds having an alkoxysilyl group, aminosilyl group.

Specific examples of the modifying agent are shown below. The compounds binding to the polymeric active terminal to form an amino group at the terminal of the polymer are not particularly limited, and examples thereof include C═N double bond compounds such as N,N′-dicyclohexylcarbodiimide.

The compounds binding to the polymeric active terminal to form an amino group and a hydroxyl group at the terminal of the polymer are not particularly limited, and examples thereof include ketone compounds having an amino group, such as N,N,N′,N′-tetramethyl-4,4′-diaminobenzophenone (Michler's ketone), N,N,N′,N′-tetraethyl-4,4′-diaminobenzophenone; cyclic urea compounds such as N,N′-dimethylimidazolidinone and N-methylpyrrolidone; cyclic amides, i.e., lactam compounds; amino group-containing epoxy compounds such as N,N,N′,N′-tetraglycidyl-1,3-bisaminomethylcyclohexane; and epoxy compounds having a nitrogen-containing heterocyclic group as described in JP2001-131227 A.

The compounds binding to the polymeric active terminal to form an alkoxysilyl group at the terminal of the polymer are not particularly limited, and examples thereof include halogenated alkylalkoxysilane compounds such as trimethoxychlorosilane, 3-chloropropyltrimethoxysilane, and 3-chloropropyltriethoxysilane; halogenated alkoxysilane compounds such as diphenoxydichlorosilane; and polyfunctional alkoxysilane compounds such as trimethoxysilane, bis(trimethoxysilyl)ethane and bis(3-triethoxysilylpropyl)ethane.

The compounds binding to the polymeric active terminal to form an alkoxysilyl group and a hydroxyl group at the terminal of the polymer are not particularly limited, and examples thereof include polysiloxane compounds having 3-glycidoxypropyltrimethoxysilane, 3-glycidoxypropyltriethoxysilane, epoxy groups, and alkoxysilyl groups in the molecule.

The compounds binding to the polymeric active terminal to form an amino group and an alkoxysilyl group at the terminal of the polymer are not particularly limited, and examples thereof include alkoxysilane compounds to which an alkyl group having an amino substituent is bonded, such as 3-dimethylaminopropyltrimethoxysilane, 3-dimethylaminopropyldimethoxymethylsilane, 3-dimethylaminopropyltriethoxysilane, bis(3-trimethoxysilylpropyl)methylamine, and bis(3-triethoxysilylpropyl)methylamine; alkoxysilane compounds to which a protected monosubstituted amino group as described in WO2007/034785 is bonded, such as N-[3-(triethoxysilyl)-propyl]-N,N′-diethyl-N′-trimethylsilyl-ethane-1,2-diamine and 3-(4-trimethylsilyl-1-piperazinyl)propyltriethoxysilane; alkoxysilane compounds to which a plurality of substituted amino groups as described in WO2008/013090 are bonded, such as N-[2-(trimethoxysilanyl)-ethyl]-N,N′,N′-trimethylethane-1,2-diamine, 1-[3-(triethoxysilanyl)-propyl]-4-methylpiperazine, 2-(trimethoxysilanyl)-1,3-dimethylimidazolidine, and bis-(3-dimethylaminopropyl)-dimethoxysilane; alkoxysilane compounds to which a nitrogen-containing heterocyclic ring as described in WO2011/040312 is bonded, such as 1,4-bis[3-(trimethoxysilyl)propyl]piperazine and 1,4-bis[3-(triethoxysilyl)propyl]piperazine; and alkoxysilane compounds to which an azasilane group as described in WO2011/129425 is bonded, such as 3-[N,N-bis(trimethylsilyl)amino]propyltrimethoxysilane, 3-[N,N-bis(trimethylsilyl)amino]propylmethyldiethoxysilane, 2,2-dimethoxy-1-(3-trimethoxysilylpropyl)-1-aza-2-silacyclopentane, and 2,2-diethoxy-1-(3-triethoxysilylpropyl)-1-aza-2-silacyclopentane.

The compounds binding to the polymeric active terminal to form a hydroxyl group at the terminal of the polymer are not particularly limited, and examples thereof include epoxy compounds such as ethylene oxide and propylene oxide; and ketone compounds such as benzophenone.

The modified vinylaromatic copolymer (A) is modified by at least one reactive functional group selected from the group consisting of an amino group, an alkoxysilyl group and a hydroxyl group.

The average number of functional groups per molecule of the functional group-modified vinylaromatic copolymer (A) can be determined from the equivalent (g/eq) of functional group in the modified vinylaromatic copolymer (A) and the number average molecular weight Mn in terms of styrene, by the following numerical expression (4).

Average number of functional groups per molecule=[(Number average molecular weight Mn)/(Average molecular weight of divinylaromatic compound unit and monovinylaromatic compound)]/(Equivalent of functional group) (4)

The equivalent of functional group in the functional group-modified vinylaromatic copolymer (A) means the mass of vinyl monomer compound such as a divinylaromatic compound unit and a monovinylaromatic compound unit which are bound to one functional group (when the copolymer contains a conjugated diene compound or other monomers, the mass of these compounds is also included). The equivalent of functional group can be calculated from the ratio of the area of a functional group-derived peak to the area of a polymer main chain-derived peak by use of ¹H-NMR or ¹³C-NMR.

The addition amount of the modifying agent in the functional group-modified vinylaromatic copolymer (A) is preferably 1 to 200 parts by mass based on 100 parts by mass of the non-modified polyfunctional vinylaromatic copolymer. The upper limit is more preferably 100 parts by weight, further preferably 60 parts by weight, still more preferably 50 parts by weight, and particularly preferably 40 parts by weight. In a case where the amount of the modifying agent added is more than 200 parts by mass, mechanical strength of a crosslinked product to be obtained from the resin composition of the present invention tends to be deteriorated. In a case where the amount added is less than 1 part by mass, the bonding tends to be deteriorated. The amount of the modifying agent having at least one functional group selected from an amino group, an alkoxysilyl group, and a hydroxyl group added to the modified vinylaromatic copolymer (A) can be determined using various analysis instruments for nuclear magnetic resonance spectroscopy and the like.

The functional group-modified vinylaromatic copolymer (A) contains 0.5 to 95.0% by mol of the structural unit (a) derived from a divinylaromatic compound.

In a case where only the structural units (a) and (b) are included in the structural unit, the molar fraction of the structural unit (a) is 0.005 to 0.95, based on the sum of the structural units (a) and (b). The molar fraction is calculated by the following numerical expression (5):

(a)/[(a)+(b)] (5)
wherein (a): the molar fraction of the structural unit (a) derived from a divinylaromatic compound, and (b): the molar fraction of the structural unit (b) derived from a monovinylaromatic compound.

A preferable lower limit of the molar fraction of the structural unit (a) is 0.006, and more preferably 0.007. A preferable upper limit is 0.80, more preferably 0.70. The molar fraction is optimally 0.01 to 0.60.

In a case where any other structural unit than the structural units (a) and (b) is included, a preferable lower limit of the content rate of the structural units (a) is 0.2% by mol, more preferably 0.4% by mol, and further preferably 0.6% by mol. A preferable upper limit of the content rate of the structural units (a) is 70% by mol, more preferably 60% by mol, and further preferably 50% by mol.

The functional group-modified vinylaromatic copolymer (A) preferably contains 5.0 to 99.5% by mol of the structural unit (b) derived from a monovinylaromatic compound. The molar fraction is 0.05 to 0.995. A preferable lower limit is 0.20, and more preferably 0.30. A preferable upper limit is 0.994, and more preferably 0.993. The molar fraction is optimally 0.40 to 0.99.

The molar fraction of the structural unit (b) is calculated by the following numerical expression (6) in a case where only the structural units (a) and (b) are included:

(b)/[(a)+(b)] (6)
wherein (a) and (b) have the same meanings as in numerical expression (5).

Even in a case where structural units other than structural units (a) and (b) are included, a preferable molar fraction of the structural unit (b) is in the above range.

The structural unit (a) derived from the divinylaromatic compound functions as a branched component to increase the amount of introduction of functional groups per molecule of the modified vinylaromatic copolymer. On the other hand, the structural unit (b) derived from the monovinyl aromatic compound does not have the second vinyl group involved in the branching reaction, and therefore plays a role in imparting functions such as moldability and compatibility derived from the backbone.

Furthermore, when the molar fraction of the structural unit (a) is less than 0.005, the bonding is insufficient, and when the molar fraction exceeds 0.95, the fabricability is deteriorated. When the molar fraction of the structural unit (b) exceeds 0.995, the bonding is deteriorated., and when the molar fraction is less than 0.05, the fabricability is deteriorated.

The functional-group modified vinylaromatic copolymer (A) can contain other structural units in addition to the above structural units (a) and (b). The detail of such other structural units is understood from the description of the production method.

The functional group-modified vinylaromatic copolymer (A) has an Mn (number average molecular weight in terms of standard polystyrene measured by use of gel permeation chromatography) of 500 to 30,000. A preferable lower limit is 600, more preferably 700, further preferably 800, and most preferably 900. A preferable upper limit is 25,000, more preferably 20,000, further preferably 15, 000, and most preferably 10, 000. If the Mn is less than 500, the amount of a functional group contained in the copolymer is reduced to result in a tendency to cause the bonding to be deteriorated. If the Mn exceeds 30, 000, not only gels are easily generated, but also the fabricability and tensile breaking elongation tend to be deteriorated. The molecular weight distribution is 30.0 or less, preferably 25.0 or less, more preferably 1.3 to 20.0. The molecular weight distribution is optimally 1.6 to 15.0. If the Mw/Mn exceeds 30.0, not only processing properties of the resin composition tend to get worse, but also gels tend to be generated.

The functional group-modified vinylaromatic copolymer (A) is soluble in a solvent selected from toluene, xylene, tetrahydrofuran, dichloroethane, or chloroform, and is advantageously soluble in all the solvents. In order that the copolymer is polyfunctional and soluble in solvents, it is necessary for the copolymer to exhibit a moderate branching degree while some of the vinyl groups of divinylbenzene remain without being crosslinked for functional group modification. Such copolymers or methods for producing the same are known in the above-mentioned patent literatures and the like. The solubility in 100 g of the solvent is preferably 50 g or more, and more preferably 80 g or more.

Next, the curable reactive resin as the component (B) is described. The component (B) is preferably a thermosetting resin containing one or more functional groups selected from the group consisting of an epoxy group, a cyanate group, a vinyl group, an ethynyl group, an isocyanate group, and a hydroxyl group. Suitable specific examples thereof are shown below.

An epoxy group-containing resin is a compound having at least two epoxy groups in its molecule, which is not particularly limited in terms of molecular structure, molecular weight, or the like as long as the resin is generally used in materials for electronic components, and examples thereof include a bisphenol A epoxy resin, a phenol novolak epoxy resin, and a cycloaliphatic epoxy resin. In addition, the epoxy resin is not limited to one type, but two or more types can be used in combination.

A hydroxyl group-containing resin includes a phenol resin which is used as a curing agent or the like for an epoxy resin. The hydroxyl group-containing resin can be used, which is not particularly limited in terms of molecular structure, molecular weight, or the like as long as the resin is generally used in materials for electronic components, and examples thereof include cresol novolak and phenol novolak. In addition, the phenol resin is not limited to one type, but two or more types can be used in combination.

A cyanate group-containing resin includes a cyanate resin, which is preferably a cyanate resin having at least two cyanate groups per molecule. Specific examples of cyanate compounds to be used in the cyanate resin include 1,3-dicyanatobenzene, 1,4-dicyanatobenzene, 1,3,5-tricyanatobenzene, 1,3-dicyanatonaphthalene, 1,4-dicyanatonaphthalene, 1,6-dicyanatonaphthalene, 1,8-dicyanatonaphthalene, 2,6-dicyanatonaphthalene, 2,7-dicyanatonaphthalene, 1,3,6-tricyanatonaphthalene, 4,4-dicyanatobiphenyl, bis(4-cyanatophenyl)methane, 2,2-bis(4-cyanatophenyl)propane, 2,2-bis(3,5-dicyclo-4-cyanatophenyl)propane, 2,2-bis(3,5-dibromo-4-cyanatophenyl)propane, bis(4-cyanatophenyl)ether, bis(4-cyanatophenyl)thioether, bis(4-cyanatophenyl)sulfone, tris(4-cyanatophenyl)phosphite, tris(4-cyanatophenyl)phosphate, and a benzene polynuclear polycyanate compound obtained by reacting a phenol resins with a cyanogen halide. One or a mixture of two or more types can be used.

A vinyl group-containing resin include a resin having at least two vinyl groups in its molecule, which is not particularly limited in terms of molecular structure, molecular weight, or the like as long as the resin is generally used in materials for electronic components, and two or more types can also be used in combination.

The vinyl group may react with the functional group-modified vinylaromatic copolymer (A) by radical polymerization when forming a cured product from the resin composition of the present invention.

The polyfunctional acryloyl compound and polyfunctional methacryloyl compound to be used as the vinyl group-containing resin of the component (B) include compounds represented by the following general formulas (2) or (3):

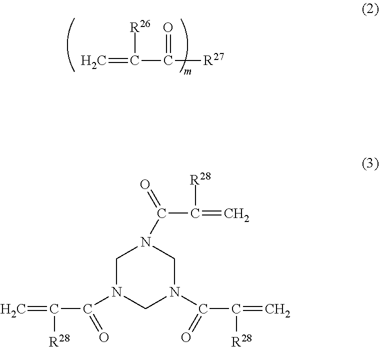

wherein m is an integer of 2 to 10, R26 and R28 each represent hydrogen or a methyl group, and R27 represents a residue of a multivalent hydroxy group-containing organic compound.

In the formula (3), examples of the R27 include a residue of an alkanepolyol such as ethyleneglycol, propyleneglycol, butanediol, neopentylglycol, hexanediol, glycerol, trimethylolethane, trimethylolpropane, pentaerythrytol, sorbitol, bis(hydroxymethy)cyclohexane, and hydrogenated bisphenol A; a residue of a polyetherpolyol such as diethyleneglycol, triethyleneglycol, tetraethyleneglycol, polyethyleneglycol, and polypropyleneglycol; an aromatic polyol in which a plurality of benzene rings are connected through a bridge part such as xylene glycol or bisphenol A, and an aromatic polyol residue such as an alkylene oxide adduct of such an aromatic polyol; a residue of a benzene polynuclear substance (usually, an decanuclear or less substance is preferably used) obtained by reacting phenol with formaldehyde; a residue derived from an epoxy resin having two or more epoxy groups; and a residue derived from a polyester resin having two or more hydroxyl groups at the terminal.

Specific examples of the polyfunctional acryloyl compound and polyfunctional methacryloyl compound include ethylene glycol diacrylate, propylene glycol diacrylate, 1,3-propanediol diacrylate, 1,4-butanediol diacrylate, 1,3-butanediol diacrylate, 1,5-pentanediol diacrylate, neopentyl glycol diacrylate, 1,6-hexanediol diacrylate, glycerol triacrylate, 1,1,1-methylol ethane diacrylate, 1,1,1-trimethylolethane triacrylate, 1,1,1-trimethylolpropane acrylate, 1,1,1-trimethylolpropane triacrylate, pentaerythritol diacrylate, pentaerythritol triacrylate, pentaerythritol tetraacrylate, sorbitol tetraacrylate, sorbitol hexaacrylate, sorbitol pentaacrylate, 1,4-hexanediol diacrylate, 2,2-bis(acryloxycyclohexane)propane, diethylene glycol diacrylate, triethylene glycol diacrylate, tetraethylene glycol diacrylate, polyethylene glycol diacrylate, polypropylene glycol diacrylate, bisphenol A-diacrylate, 2,2-bis(4-(2-acryloxyethoxy)phenyl)propane, 2,2-bis(4-(acryloxy-di-(ethyleneoxy)phenyl))propane, 2,2-bis(4-(acryloxy-poly-(ethyleneoxy)phenyl))propane; multivalent acrylates of phenolic resin initial condensates; epoxy acrylates obtained by reacting bisphenol A epoxy resins, novolak epoxy resins, cycloaliphatic epoxy resins, phthalic acid diglycidyl ester, polycarboxylic acids and the like with acrylic acid; polyester polyacrylates obtained by reacting polyesters having two or more hydroxyl groups at the terminals with acrylic acid; methacrylates of the acrylates as described above; and ones in which hydrogen atoms of these compounds are partly substituted with halogen, for example, 2,2-dibromomethyl-1,3-propanediol dimethacrylate.

Examples of the representative polyfunctional (meth)acryloyl compounds having a triazine ring include hexahydro-1,3,5-triacryloyl-s-triazine and hexahydro-1,3,5-trimethacryloyl-s-triazine.

The polyfunctional maleimide to be used as the vinyl group-containing resin include a compound represented by the following general formula (4):

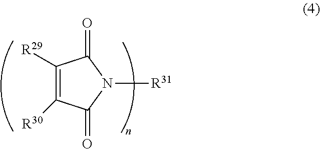

wherein n is an integer of 2 to 10, R29 and R30 each represent hydrogen, halogen, or a lower alkyl group, and R31 represents a divalent to decavalent aromatic or aliphatic organic group.

The polyfunctional maleimide in the formula (4) is produced through a reaction of maleic anhydrides with polyamine having 2 to 10 amino groups in a molecule to form maleimide acid, followed by cyclodehydration of the maleamic acid.

Examples of the preferable polyamine include metaphenylene diamine, paraphenylene diamine, metaxylylene diamine, paraxylylene diamine, 1,4-cyclohexanediamine, 1,3-cyclohexanediamine, hexahydroxylylenediamine, 4,4-diaminobiphenyl, bis(4-aminophenyl)methane, bis(4-aminophenyl)ether, bis(4-aminophenyl)sulfone, bis(4-amino-3-methylphenyl)methane, bis(4-aminophenyl)cyclohexane, 2,2-bis(4-aminophenyl)propane, 2,2-bis(4-amino-3-methylphenyl)propane, bis(4-amino-3-chlorophenyl)methane, 2,2-bis(3,5-dibromo-4-aminophenyl)methane, 3,4-diaminophenyl-4′-aminophenylmethane, 1,1-bis(4-aminophenyl)-1-phenylethane, melanins having s-triazine rings, and polyamine obtained by reacting aniline with formaldehyde (usually, a substance with 10 benzene nuclei or less is preferably used).

An unsaturated polyester to be used as the vinyl group-containing resin include a substance obtained by reacting glycols with unsaturated polybasic acid or saturated polybasic acid, or anhydride, ester, or acid chloride thereof, each of which is generally known.

Examples of the representative glycols include ethylene glycol, propylene glycol, diethylene glycol, difropylene glycol, neopentyl glycol, 1,3-butanediol, 1,4-butanediol, 1,6-hexanediol, bisphenol A hydride, bisphenol A propylene oxide adduct, and dibromoneopentol glycol.

Examples of the representative unsaturated polybasic acid include maleic anhydride, fumaric acid, and itaconic acid. Examples of the representative saturated polybasic acid include phthalic anhydride, isophthalic acid, terephthalic acid, tetrahydrophthalic anhydride, methyltetrahydrophthalic anhydride, endomethylenetetrahydrophthalic anhydride, adipic acid, sebacic acid, tetto acid, and tetrabromophthalic anhydride.

Details of the unsaturated polyester may be referred to “Polyester Resin Handbook”, written by Eichiro Takiyama, published by The Nikkankogyo Shimbun, Ltd. (1988), for example.

An isocyanate group-containing resin include a resin having at least two isocyanate groups in its molecule, which is not particularly limited in terms of molecular structure, molecular weight, or the like as long as the resin is generally used in materials for electronic components, and two or more types can also be used in combination. Examples of the resin containing the above isocyanate group include 2,4-toluene diisocyanate, 2,6-toluene diisocyanate, metaphenylene diisocyanate, paraphenylene diisocyanate, metaxylylene diisocyanate, 1,5-naphthalene diisocyanate, 4,4-diphenylmethane diisocyanate, tolidine diisocyanate, tetramethylxylene diisocyanate, isophoron diisocyanate, cyclohexane-1,4-diisocyanate, lysine isocyanate, triphenylmethane triisocyanate, tris (isocyanatophenyl)thiophosphate, 1,6,11-undecane triisocyanate, 1,8-diisocyanate-4-isocyanate methyl octane, 1,3,6-hexamethylene triisocyanate, bicycloheptane triisocyanate, and polymethylene polyphenyl isocyanate.

The resin containing such an isocyanate group can also be used by converting into polyfunctional block isocyanate with various block agents. Examples of the block agent that can be used include alcohols, phenols, oximes, lactam, malonate, acetoacetate ester, acetylacetone, amides, imidazoles, and sulfites, each of which is known.

The thermosetting resin (B) is preferably a thermosetting resin having a post-curing glass transition temperature of 130° C. or higher or an elastic modulus at 140° C. of 500 MPa or more, further preferably a post-curing glass transition temperature of 150 to 300° C. or an elastic modulus at 160° C. of 500 to 3000 MPa.

Next the thermoplastic resin as the component (C) is described.

Examples of the thermoplastic resin (C) include polyolefins such as polyethylene, polypropylene, polybutene, ethylene-propylene copolymers, and poly(4-methyl-pentene) and derivatives thereof; polyamides such as nylon 4, nylon 6, nylon-6,6, nylon-6,10, and nylon-12 and derivatives thereof; polyesters such as polyethylene terephthalate, polybutylene terephthalate, polyethylene naphthalate, and polyethylene terephthalate/polyethylene glycol block copolymers and derivatives thereof; polystyrenes such as polyphenylene ether, modified polyphenylene ether, polycarbonate, polyacetal, polysulfone, polyvinyl chloride and copolymers thereof, and polyvinylidene chloride and copolymers thereof, polymethyl methacrylates, ester acrylate (or methacrylate) copolymers, polystyrenes, acrylonitrile styrene copolymers, and acrylonitrile styrene butadiene-based copolymers, and copolymers thereof; polyvinyl acetates; polyvinyl formals; polyvinyl acetal; polyvinyl butylals; ethylene vinyl acetate copolymers and hydrolysates thereof; polyvinyl alcohols; rubbers such as styrene conjugated diene block copolymers; rubbers such as hydrogenated styrene conjugated diene block copolymers; rubbers such as polybutadiene and polyisoprene; polyvinyl ethers such as polymethoxyethylene and polyethoxyethylene; polyacrylamide; polyphosphasens; polyethersulfone; polyetherketone, polyetherimide; polyphenylene sulfide; polyamide imide; thermoplastic polyimide; liquid crystal polymers such as aromatic polyesters; and side-chain liquid crystal polymers containing liquid crystal components in the side chains, or thermoplastic block copolymers having at least one functional group selected from an epoxy group, carboxylic acid group, and maleic anhydride group.

Of the thermoplastic resins, when the thermoplastic resin has a glass transition temperature of 70° C. or lower at which the effect of toughness can be enhanced, an elastomer excellent in rubber elasticity is preferred for the purpose of enhancing the crack resistance and bonding of the resin composition of the present invention or a cured product thereof. Examples of such an elastomer include a thermoplastic elastomer and a liquid elastomer. Examples of the thermoplastic elastomer include polystyrene-based thermoplastic elastomers, such as styrene-butadiene copolymers and styrene-isoprene copolymers, polyolefin-based thermoplastic elastomers, polyamide-based elastomers, and polyester-based elastomers.

To further enhance the effect of toughness, a block copolymer having a polymer segment with a glass transition temperature of 20° C. or lower is more preferably used. A block copolymer having a polymer segment with a glass transition temperature of 0° C. or lower is further preferably used. The block copolymer having the polymer segment with a glass transition temperature of 20° C. or lower preferably include rubbers such as a styrene conjugated diene block copolymer; and rubbers such as a hydrogenated styrene conjugated diene block copolymer. Hydrogenated rubbers such as a hydrogenated styrene conjugated diene block copolymer are most preferred from the viewpoint of thermo-oxidative degradation resistance of the curable resin composition of the present invention. A structure of the hydrogenated block copolymer is obtained through hydrogenation of a block copolymer formed of a polymer block A mainly containing at least one vinylaromatic compound, and a polymer block B mainly containing at least one conjugated diene compound. The hydrogenated styrene conjugated diene block copolymer is obtained through hydrogenation of a vinylaromatic compound/conjugated diene compound block copolymer having a structure such as:

A-B;

A-B-A;

B-A-B-A;

[A-B-]n-Si; and

[B-A-B-]n-Si
(n is the number of polymer chains attached to Si and represents an integer of 1 to 4). This hydrogenated block copolymer contains the vinylaromatic compound in an amount of 5 to 85 wt %, preferably 10 to 70 wt %, and more preferably 15 to 40 wt %.

Regarding a block structure, the polymer block A mainly containing a vinylaromatic compound has a structure of a polymer block consisting solely of the vinylaromatic compound, or a structure of a copolymer block including the vinylaromatic compound and the hydrogenated conjugated diene compound and containing the vinylaromatic compound in an amount of more than 50% by weight, and preferably 70% by weight or more. The polymer block B mainly containing a hydrogenated conjugated diene compound has a structure of a polymer block consisting solely of the hydrogenated conjugated diene compound, or a structure of a copolymer block including the hydrogenated conjugated diene compound and the vinylaromatic compound and containing the hydrogenated conjugated diene compound in an amount of more than 50% by weight, and preferably 70% by weight or more.

In the polymer block A mainly containing such a vinylaromatic compound and the polymer block B mainly containing a hydrogenated conjugated diene compound, distribution of the hydrogenated conjugated diene compound or the vinylaromatic compound in a molecular chain of each polymer block may be in a random, tapered (monomer components increase or decrease along a molecular chain), or partly block form, or in a form of any combination thereof. In the case where two or more of the polymer blocks mainly containing a vinylaromatic compound and the polymer blocks mainly containing a hydrogenated conjugated diene compound, respectively, are present, the polymer blocks may have an identical structure or different structures.

As the vinylaromatic compound forming the hydrogenated block copolymer, one or more types of compounds may be selected from styrene, α-methylstyrene, p-methylstyrene, vinyltoluene, and p-tertiary butylstyrene, for example. Of those, styrene is preferred. As a conjugated diene compound before hydrogenation forming the hydrogenated conjugated diene compound, one or more types of compounds may be selected from butadiene, isoprene, 1,3-pentadiene, and 1,3-dimethyl-1,3-butadiene, for example. Of those, butadiene, isoprene, and a combination thereof are preferred. Butadiene is most preferred from the viewpoint of compatibility with the component (A) and the component (B) of the present invention.

The number average molecular weight of the hydrogenated block copolymer having the above structure is not particularly limited, but the number average molecular weight can be in the range of 5000 to 1,000,000, preferably 10,000 to 500,000, and more preferably 30000 to 300,000. Furthermore, the molecular structure of the hydrogenated block copolymer may be linear, branched, radial, or any combination thereof.

Any production method for these block copolymers can be used to obtain block copolymers with the above structure (even if some of the conjugated diene compounds in the block copolymer are hydrogenated). For example, a vinylaromatic compound-conjugated diene compound block copolymer is synthesized in an inert solvent using a lithium catalyst or the like by the method described in JP 40-23798 B, and then hydrogenated in the presence of a hydrogenation catalyst in an inert solvent by the methods described in JP 42-8704 B and JP 43-6636 B, particularly preferably the methods described in JP 59-133203 A and JP 60-79005 A, whereby the block copolymer and hydrogenated block copolymer to be used in the present invention can be synthesized. At this point, at least 80% of the aliphatic double bonds based on the conjugated diene compound of the vinylaromatic compound-conjugated diene compound block copolymer are hydrogenated, whereby the polymer block mainly containing the conjugated diene compound can be converted into an olefinic compound polymer block in terms of morphology. The hydrogenation ratio of the aromatic double bond based on the vinylaromatic compound copolymerized in the polymer block A mainly composed of the vinylaromatic compound and, if necessary, the polymer block B mainly composed of the conjugated diene compound is not particularly limited but is preferably 20% or less.

The block copolymer also includes a modified block copolymer to which a molecular unit containing a dicarboxylic acid group or a derivative thereof is bonded within a range that does not impair the properties. The molecular unit containing a dicarboxylic acid group or a derivative thereof can be used usually in the range of 0.05 to 5% based on the block copolymer serving as a substrate. Examples of the modifying agent containing a dicarboxylic acid group or a derivative thereof include maleic acid, fumaric acid, chloromaleic acid, itaconic acid, cis-4-cyclohexene-1,2-dicarboxylic acid, and anhydrides, esters, amides, and imides of these dicarboxylic acids. Specific examples of preferred modifying agents include maleic anhydride, maleic acid, and fumaric acid.

The method for producing the modified block copolymer is not particularly limited, but a method of reacting the block copolymer with the modifying agent in a molten state using an extruder or the like with or without the use of a radical initiator is usually used. The component (C) of the resin composition of the present invention preferably improves the toughness and adhesion of the resin composition after curing, which does not adversely affect the other mechanical properties and dielectric characteristics of the cured composition.

Next, the blending ratio of the resin composition of the present invention containing the component (A), the component (B), and/or the component (C) can be changed in a wide range, but the amounts of the components (A), (B), and (C) blended (weight ratio) need to satisfy the following numerical expressions (1) to (3).

$$( A ) + ( B ) + ( C ) = 100 ( wt \% ) \qquad ( 1 )$$

$$( A ) = 0.1 to 50 ( wt \% ) \qquad ( 2 )$$

$$( B ) + ( C ) = 50 to 99.9 ( wt \% ) \qquad ( 3 )$$

The amount of the component (A) blended is required to be 0.1 to 50 wt %. The blending amount is more preferably 0.2 to 40 wt %, further preferably 0.4 to 20 wt %, and particularly preferably 0.5 to 10 wt %. If the amount of the component (A) blended is too small, the improvement in bonding is insufficient, whereas if it is too large, the mechanical strength and heat resistance are deteriorated.

It is essential to contain at least one of the component (B) and the component (C). The component (B) and the component (C) may be blended individually or in combination, which may appropriately be selected depending on the purpose and application.

The amount of the component (B) and the component (C) blended is required to be 50 to 99.9 wt % in total, more preferably 60 to 99.8 wt %, further preferably 80 to 99.6 wt %, and particularly preferably 90 to 99.5 wt %. If only the component (B) and the component (C) but not the component (A) are blended, bonding with different inorganic materials such as metals and glasses is deteriorated.

The amount of the component (B) blended can be selected from the range of 0 to 99.9 wt %, preferably 10 to 99.8 wt %, more preferably 20 to 99.6 wt %, and particularly preferably 30 to 99.5 wt %.

The amount of the component (C) blended can also be selected from the range of 0 to 99.9 wt %, preferably 10 to 99.8 wt %, more preferably 20 to 99.6 wt %, and particularly preferably 30 to 99.5 wt %.

In addition to the components (A), (B), and (C), the resin composition of the present invention may contain, as the component (D), a curing catalyst that generates, by heating or light, a cationic or radical active species capable of initiating the polymerization of vinyl groups in order to lower the reaction temperature and promote the crosslinking reaction of unsaturated groups when curing by causing a crosslinking reaction by means of heating or the like, as described below.

The amount of the curing catalyst (D) is 0.0005 to 10 wt %, preferably 0.01 to 8 wt %, based on the content of the vinyl group-containing resin in the components (A), (B), and (C).

Examples of a curing catalyst generating cationic or radical active species, which is able to initiate the polymerization of a vinyl group, by heating or light are shown below. Examples of a cationic polymerization initiator include diallyl iodonium salt, triallyl sulfonium salt, and aliphatic sulfonium salt each of which uses BF₄, PF₆, AsF₆, or SbF₆ as a pairing anion. Commercially available products such as SP-70, SP-172, and CP-66 manufactured by ADEKA CORPORATION, CI-2855 and CI-2823 manufactured by Nippon Soda Co., Ltd., and SI-100L and SI-150L manufactured by Sanshin Chemical Industry Co., Ltd can be used.

Examples of the representative radical initiator include, but are not limited to, peroxides such as benzoyl peroxide, cumene hydroperoxide, 2,5-dimethylhexane-2,5-dihydroperoxide, 2,5-dimethyl-2,5-di(t-butylperoxy)hexine-3, di-t-butyl peroxide, t-butyl cumyl peroxide, α,α′-bis(t-butylperoxy-m-isopropyl)benzene, 2,5-dimethyl-2,5-di(t-butylperoxy)hexane, dicumyl peroxide, di-t-butyl peroxy isophthalate, t-butyl peroxy benzoate, 2,2-bis(t-butylperoxy) butane, 2,2-bis(t-butylperoxy) octane, 2,5-dimethyl-2,5-di (benzoylperoxy)hexane, di (trimethylsilyl) peroxide, trimethylsilyl triphenylsilyl peroxide, and tetramethylbutyl hydroperoxide. Although not a peroxide, 2,3-dimethyl-2,3-diphenylbutane can also be used as a radical initiator. However, the initiator which can be used to cure the resin composition of the present invention is not limited to these examples.

In order to enhance storage stability, a polymerization inhibitor can be added to the resin composition of the present invention. The amount added is preferably within such a range that does not significantly impair the dielectric characteristics and reactivity during curing, and is desirably 0.0005 to 5 wt % based on the components (A), (B), and (C), particularly the component (B). When the polymerization inhibitor is added in an amount within the range described above, an excessive crosslinking reaction during storage can be suppressed, and no remarkable hindrance to curing occurs during curing. Examples of the polymerization inhibitor include quinones such as hydroquinone, p-benzoquinone, chloranil, trimethylquinone, and 4-t-butylpyrocatechol, and aromatic diols.

In addition, a curing catalyst suitable for curing a thermosetting resin having a reactive group other than a vinyl group can be added. Specific examples of the curing catalyst suitable for such a thermosetting resin having a reactive group other than a vinyl group include tertiary amines such as triethylamine and triethanolamine, and imidazoles such as 2-ethyl-4-imidazole and 4-methylimidazole, as curing agents suitable for epoxy resins. Examples of a catalyst suitable for the cyanate resin include a mineral acid, a Lewis acid, salts such as sodium carbonate and lithium chloride, and a phosphoric acid ester such as tributylphosphine. Examples of the catalyst and curing agent suitable for the isocyanate resin include amines, an organic metal, and polyhydric alcohol, as described in pp. 118 to 123 of “Polyurethane Resin Handbook”, edited by Keiji Iwata, published by The Nikkankogyo Shimbun, Ltd. (1987). However, the curing agent of a thermosetting resin to be used as the component (B) of the resin composition of the present invention is not limited to these examples.

The curing catalyst, initiator, curing accelerator, and the like may appropriately be selected and used according to the type of the components (A), (B), and (C).

A flame retardant can be blended as the component (E) in the resin composition of the present invention, whereby the cured product of the resin composition may have further enhanced flame retardancy. Specific examples of the flame retardant include, but are not particularly limited to, halogen flame retardants such as brominated flame retardants and phosphorous flame retardants. Specific examples of the halogen flame retardants include brominated flame retardants such as pentabromodiphenyl ether, octabromodiphenyl ether, decabromodiphenyl ether, tetrabromobisphenol A, and hexabromocyclododecane; chlorinated flame retardants such as chlorinated paraffins. Specific examples of the phosphorous flame retardants include phosphate esters such as condensed phosphate esters and cyclic phosphate esters; phosphazene compounds such as cyclic phosphazene compounds; phosphinate flame retardants such as metal salts of phosphinic acid, including aluminum dialkylphosphinates; and melamine flame retardants such as melamine phosphates and melamine polyphosphates. These flame retardants may be used alone, or two or more kinds thereof may be used in combination.

Furthermore, a filling agent can be blended as the component (F) in the resin composition of the present invention. Examples of the inorganic filling material include, but are not particularly limited to, those added to enhance heat resistance and flame retardancy of the cured product of the resin composition. The inclusion of an inorganic filling material can enhance heat resistance, flame retardancy, and the like. The resin composition of the present invention, when compared with an epoxy resin composition for an ordinary insulating base material, has a high crosslinking density but has a low cohesive force of molecules due to the less polar chemical structure, and thus a cured product thereof tends to have a high thermal expansion coefficient, especially a thermal expansion coefficient α at a temperature in excess of the glass transition temperature. The inclusion of an inorganic filling material makes it possible to reduce the thermal expansion coefficient of the cured product, especially the thermal expansion coefficient α at a temperature in excess of the glass transition temperature, and to increase the toughness of the cured product, while maintaining excellent dielectric characteristics, as well as excellent heat resistance and flame retardancy of the cured product, and having a low viscosity when rendered into a varnish. Specific examples of the inorganic filling materials include silica, alumina, talc, aluminum hydroxide, magnesium hydroxide, titanium oxide, mica, aluminum borate, barium sulfate, and calcium carbonate. Although the inorganic filling material may be used as it is, use of the inorganic filling material after surface treatment with a vinylsilane-type, styrylsilane-type, methacrylsilane-type, or acrylsilane-type silane coupling agent is preferred. A metal clad laminate obtained using a resin composition formulated with an inorganic filling material that has been surface-treated with such a silane coupling agent tend to have a high heat resistance at the time of moisture absorption and also tend to have a high interlaminar peel strength.

When the resin composition of the present invention contains (E) a flame retardant and/or (F) a filling agent, the content thereof is preferably less than 80% by mass, more preferably 5 to 75% by mass, and further preferably 10 to 70% by mass, based on 100 (parts by weight) of the resin component (monomer, resin, or prepolymer) of the resin composition of the present invention, with respect to the composition.

The resin composition of the present invention may various other additives. Examples of such other additives include defoaming agents such as silicone-based defoaming agents and acrylate ester-based defoaming agents, thermal stabilizers, antioxidants, antistatic agents, ultraviolet absorbers, dyes and pigments, lubricants, and dispersants such as wetting dispersants. Known substances such as phenolic antioxidants, sulfur-based antioxidants, phosphorus-based antioxidants, amine-based antioxidants can be used as the antioxidants.

To produce a prepreg, the resin composition of the present invention can be made into a resin varnish by being prepared into varnish form, for the purpose of impregnating a base material (fibrous base material) for forming the prepreg, in order to constitute a circuit board material for forming a circuit board or the like.

The resin varnish contains the polyfunctional vinylaromatic copolymer, the radical polymerization initiator, and a solvent. The resin varnish is suitable for circuit boards. The use of the circuit board materials specifically includes printed wiring boards, printed circuit boards, flexible printed wiring boards, and build-up wiring boards.

The resin varnish is, for example, prepared as follows.

First, components that can dissolve in an organic solvent, such as a polyfunctional vinylaromatic copolymer and a curable reactive resin, are charged into and dissolved in the organic solvent. This may be accomplished with heating, if necessary. Thereafter, components such as the inorganic filling material that are used if necessary and are insoluble in the organic solvent are added, with dispersion using, for example, a ball mill, a bead mill, a planetary mixer, or a roll mill until a desired state of dispersion is achieved, to prepare a varnish-like curable resin composition. The organic solvent used herein is not particularly limited as long as it can dissolve the polyfunctional vinylaromatic copolymer and the curable reactive resin without hindering curing reactions. Specifically, for example, in the present invention, an organic solvent is used, if necessary, but the type thereof is not particularly limited as long as it is compatible with the resin composition used. Typical examples thereof include ketones such as acetone, methyl ethyl ketone, and methyl isobutyl ketone; esters such as ethyl acetate, propyl acetate, and butyl acetate; polar solvent such as dimethylacetamide and dimethylformamide; and aromatic hydrocarbon solvents such as toluene and xylene, which can be used singly or in mixtures of two or more types as appropriate. Aromatic hydrocarbons such as benzene, toluene, and xylene are preferable, from the viewpoint of dielectric characteristics.

The amount of the organic solvent to be used in preparing the resin varnish is preferably 5 to 900% by weight, more preferably 10 to 700% by weight, and particularly preferably 20 to 500% by weight, based on 100% by weight of the resin composition of the present invention. In a case where the resin composition of the present invention is an organic solvent solution such as a resin varnish, the amount of the organic solvent is not factored in the calculation of the composition.

The cured product obtained by curing the resin composition of the present invention can be used as a molded article, a laminated product, a cast product, an adhesive, a coating, or a film. For example, a cured product of a semiconductor encapsulating material is a cast product or a molded article, and a method for obtaining a cured product for such applications may involve casting a curable resin composition or molding the curable resin composition using a transfer molding machine, an injection molding machine, or the like, whereupon the cured product can be obtained by further heating at 80° C. to 230° C. for 0.5 to 10 hours. A cured product of a varnish for a circuit board is a laminated product, and a method for obtaining such a cured product may involve impregnating a base material such as glass fibers, carbon fibers, polyester fibers, polyamide fibers, alumina fibers, and paper, with the varnish for a circuit board, followed by heating and drying, to yield a prepreg. Then, prepreg sheets are laminated with each other or with a metal foil, such as a copper foil, and subjected to heat press molding.

An inorganic high-dielectric powder such as barium titanate or an inorganic magnetic body such as ferrite is blended into the curable composition or varnish, to thereby render the composition or varnish yet better as a material for electronic components, in particular as a material for high-frequency electronic components.

The resin composition of the present invention can be used by being affixed to a metal foil (meaning of which includes a metal sheet; the same applies hereinafter), similarly to the cured composite material described below.

Next, a composite material of the resin composition of the present invention and a cured product thereof are described. A base material is added to the composite material by the resin composition of the present invention in order to increase mechanical strength and dimensional stability.

Known materials can be used as such a base material, and examples thereof include various types of cloth and paper, for instance, glass cloth such as roving cloth, cloth, chopped mats, and surfacing mats; inorganic fiber cloth including synthetic and natural cloth, such as asbestos cloth and metal fiber cloth; woven fabrics and nonwoven fabrics obtained from liquid-crystal fibers such as wholly-aromatic polyamide fibers, wholly-aromatic polyester fibers, and polybenzoxazole fibers; woven fabrics and nonwoven fabrics obtained from synthetic fibers such as polyvinyl alcohol fibers, polyester fibers, and acrylic fibers; natural fiber fabrics such a cotton, hemp, and felt; carbon fiber cloth; and natural cellulosic cloth such as kraft paper, cotton paper, and paper-glass mixed paper. The foregoing can be used alone or in combination with two or more types.

The proportion of the base material in the curable composite material is 5 to 90 wt %, preferably 10 to 80 wt % and further preferably 20 to 70 wt %. When the proportion of the base material is less than 5 wt %, the dimensional stability and strength after curing of the composite material are insufficient, while when the proportion is more than 90 wt %, the dielectric characteristics of the composite material become impaired, which is undesirable.

In the curable composite material of the present invention, a coupling agent can be used, if necessary, for the purpose of improving bonding at the interface between the resin and the base material. Ordinary coupling agents can be used herein, for example, silane coupling agents, titanate coupling agents, aluminum coupling agents, and zircoaluminate coupling agents.

Examples of the method for producing the composite material of the present invention include a method of dissolving or dispersing uniformly the resin composition of the present invention and other components, if necessary, in a solvent, such as an aromatic solvent or ketone-based solvent, or a mixed solvent thereof, and then impregnating a base material, followed by drying. Impregnation is accomplished, for example, through immersion (dipping) or coating. Impregnation can be repeated a plurality of times, if necessary, and the impregnation can be repeated using a plurality of solutions having different compositions and/or concentrations to adjust the resin composition and amount of resin as ultimately desired.

The composite material of the present invention may be cured according to a method such as heating to obtain a curable composite material. The production method is not particularly limited, and for example, a plurality of layers of the composite material of the present invention can be layered on top of each other, followed by heat curing simultaneously with bonding of the layers to each other, under heating and pressing to obtain a cured composite material with the desired thickness. A cured composite material which has been once bonded and cured can be combined with a further curable composite material to obtain a cured composite material having a new layer build-up. Lamination molding and curing can be carried out simultaneously using an ordinary heat press or the like but may each be carried out independently. In other words, an uncured or semi-cured composite material obtained beforehand through lamination molding can be cured by being thermally treated or processed according to another method.

The resin composition or the composite material of the present invention can be cured, or molded and cured, at a temperature of 80 to 300° C. and a pressure of 0.1 to 1000 kg/cm2 for 1 minute to 10 hours, and more preferably at a temperature of 150 to 250° C. and a pressure of 1 to 500 kg/cm2 for 1 minute to 5 hours.

The laminate of the present invention is composed of a layer of the composite material of the present invention and a metal foil layer. Examples of the metal foil used herein include a copper foil and an aluminum foil. The thickness of the metal foil is not particularly limited, but is in a range from 3 to 200 μm and more preferably in a range from 3 to 105 μm.

Examples of the method for producing the laminate of the present invention include a method of laminating a curable composite material, obtained from the curable resin composition of the present invention explained above and from a base material, with a metal foil, to yield a layer build-up according to a desired purpose, followed by heat curing simultaneously with bonding of the layers to each other under heating and pressing. In the laminate of the curable resin composition of the present invention, the cured composite material and the metal foil are laminated according to an arbitrary layer build-up. The metal foil may be used both as a surface layer and as an intermediate layer. In addition to the above, a multilayer laminate can be achieved through repeated lamination and curing a plurality of times.

An adhesive can be used for bonding to the metal foil. Examples of the adhesive include, but are not particularly limited to, an epoxy-based, acrylic-based, phenolic-based or cyanoacrylate-based adhesive. Lamination molding and curing can be carried out under the same conditions as in the production of the cured composite material of the present invention.

The resin composition of the present invention can be molded into a film, which is one embodiment of the resin composition of the present invention. The thickness of the film is not particularly limited, but is in the range of 3 to 200 μm, and more preferably 3 to 105 μm.

Examples of the method for producing the film of the present invention include, but are not particularly limited to, a method of dissolving or dispersing uniformly the curable resin composition in a solvent, such as an aromatic solvent or ketone-based solvent, or a mixed solvent thereof, and then applying the resulting product onto a resin film such as a PET film, followed by drying. Application can be repeated a plurality of times, if necessary, and the application can be repeated using a plurality of solutions having different compositions and/or concentrations to adjust the resin composition and amount of resin as ultimately desired.

The resin-coated metal foil of the present invention is composed of the curable composition of the present invention and a metal foil. Examples of the metal foil used herein include a copper foil and an aluminum foil. The thickness of the metal foil is not particularly limited, but is in a range from 3 to 200 μm and more preferably in a range from 5 to 105 μm.

Examples of the method for producing the resin-coated metal foil of the present invention include, but are not particularly limited to, a method of dissolving or dispersing uniformly the resin composition in a solvent, such as an aromatic solvent or ketone-based solvent, or a mixed solvent thereof, and then applying the resulting product onto metal foil, followed by drying. Application can be repeated a plurality of times, if necessary, and the application can be repeated using a plurality of solutions having different compositions and/or concentrations to adjust the resin composition and amount of resin as ultimately desired.

The resin composition of the present invention can be processed into a molding material, a sheet, or a film and used as a low dielectric material, an insulating material, a heat-resistant material, a structural material, or the like which satisfies the characteristics such as low dielectric constant, low water-absorption, and high thermostability in the fields of electrical industries, spacecraft and aircraft industries, automotive industries, and the like. In particular, the resin composition of the present invention can be used as a single-sided or double-sided multilayer printed board, a flexible printed board, a build-up board, or the like. The resin composition of the present invention is applicable to a semiconductor-related material or an optical material, and also to paint, a photosensitive material, an adhesive, a sewage treatment agent, a heavy metal scavenger, an ion-exchange resin, an antistatic agent, an antioxidant, an anti-fogging agent, a rust inhibitor, a dye-proofing agent, a fungicide, an insect repellent, a medical material, a flocculant, a surfactant, a lubricant, a solid fuel binder, a conductive treatment agent, a resin modification material, an asphalt modification material, a plasticizer, a sintering binder, and the like.

The resin composition of the present invention has high-level dielectric characteristics (low dielectric constant and low loss tangent)) even after a severe thermal history, affords a cured product having high adhesion reliability, even in harsh environments, and is excellent in resin flowability and wiring embedding planarity with low linear expansion. Accordingly, a cured molded article that accommodates the smaller sizes and thinner profiles strongly demanded in recent years while free of molding failure phenomena such as warping or the like can be provided as a dielectric material, an insulating material, a heat-resistant material, a structural material, or the like in the fields of electrical and electronic industries, spacecraft and aircraft industries, and the like. Furthermore, a resin composition, a cured product, or a material containing the cured product with excellent reliability can be realized due to the wiring embedding planarity and excellent adhesion to different materials.

### EXAMPLES

Next, the present invention is described with reference to Examples, but the present invention is not limited to these Examples. The parts in each example are parts by weight.

The measurement and evaluation methods of each physical property were as shown below.

### 1) Molecular Weight and Molecular Weight Distribution of Polymer

The measurements of molecular weight and molecular weight distribution of the polymer were performed using GPC (HLC-8220 GPC, manufactured by Tosoh Corporation) as well as TSKgel Multipore H_{XL}-M: 2 columns and TSKgel G1000H_{XL}: one column, as analysis columns, and TSK guard column MP (XL): one column, as a guard column, manufactured by Tosoh Corporation, with tetrahydrofuran (THF) as a solvent, a flow rate of 1.0 ml/min, a column temperature of 38° C., and a calibration curve with monodisperse polystyrene.

### 2) Structure of Polymer

The structure was determined using a JNM-LA600 nuclear magnetic resonance spectrometer manufactured by JEOL Ltd. through ¹³C-NMR and ¹H-NMR analysis. Chloroform-di was used as the solvent, and a resonance line of tetramethylsilane was used as an internal standard.

### 3) Analysis of Structural Unit (Modified Functional Group)

In the calculation of the structural unit (modified functional group), the amount of introduction of a specified structural unit was calculated from the data on the total amount of various structural units (monomers and modified functional groups) introduced into the copolymer, obtained by GC analysis, in addition to the measurements results of ¹³C-NMR and 1H-NMR, and the specified structural unit (modified functional group) contained in one molecule of the copolymer was calculated from the amount of introduction of the specified structural unit and the number average molecular weight obtained by GPC measurement.

### 4) Thermogravimetric Measurement (TGA)

The weight loss at 350° C. (TGA₃₅₀) was determined according to JIS K7120.

### 5) Haze

A sample prepared by dissolving 0.5 g of copolymer rubber in 100 g of toluene was put into a quartz cell, and the Haze (turbidity) thereof was measured using an integrating sphere type light transmittance measurement device (SZ-290, manufactured by NIPPON DENSHOKU INDUSTRIES CO., LTD.) with toluene as a reference sample.

### Synthetic Example 1 Synthesis of Functional Group-Modified Vinylaromatic Copolymer (A-1)

270 ml (210.3 g) of cyclohexane and 5 g of a cyclohexane solution containing 1.73 ml (9.0 mmol) of 2,2-di(2-tetrahydrofuryl)propane were charged and 50 g of a cyclohexane solution containing 2.88 g (45.0 mmol) of n-butyllithium as pure content was added at 50° C., followed by the addition of 4.73 g of DVB-630 (the following structural formula) (22.9 mmol of a divinylbenzene (mixture of m-isomer and p-isomer) component and 13.4 mmol of an ethylvinylbenzene (mixture of m-isomer and p-isomer) component) and

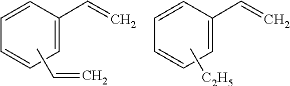

27.96 g (269 mmol) of styrene (the following structural formula),

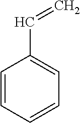

which had been cleared of impurities in advance, to initiate the polymerization. The temperature of the reaction solution increased due to the polymerization heat, reaching a maximum temperature of 81° C. After the completion of the polymerization reaction, 10.63 g (45.0 mmol) of 3-glycidoxypropyltrimethoxysilane (GPTMS: the following structural formula)

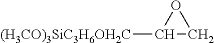

was added to the reactor as a modifying agent and subjected to a modification reaction for 30 minutes to obtain a polymer solution containing a functional group-modified vinylaromatic copolymer. After the completion of the polymerization reaction, 10.62 g (90.0 mmol) of succinic acid was added and stirred, and then filtration was performed.

GPTES was a modifying agent generating a hydroxyl group by a reaction of a glycidyl group, present together with an alkoxysilyl group, mainly with carbanion as an active species.

The obtained polymerization solution was concentrated by devolatilization to obtain 42.89 g (yield: 99.0 wt %) of a functional group-modified vinylaromatic copolymer A-1 in solid content equivalent yield.

The analysis results of the functional group-modified vinylaromatic copolymer A-1 are shown in Table 1.

The obtained functional group-modified vinylaromatic copolymer A-1 had an Mn of 4520, an Mw of 8870, and an Mw/Mn of 1.96. GC analysis, 13C-NMR and 1H-NMR analysis were performed, and the functional group-modified vinylaromatic copolymer A-1 contained 6.55% by mol (6.88 wt %) of a divinylbenzene-derived structural unit, 3.79% by mol (4.04 wt %) of an ethylvinylbenzene-derived structural unit, 76.8% by mol (64.5 wt %) of a structural unit derived from styrene, and 12.9% by mol (24.5 wt %) of a structural unit derived from 3-glycidoxypropyltrimethoxysilane. Since the crosslinked structural unit (al) derived from the divinylaromatic compound represented by the formula (1) was 6.55% by mol (6.88 wt %), the degree of crosslinking (al/a) was 1.00. Since the divinylbenzene-derived structural unit (a2) having a residual vinyl group, contained in the functional group-modified vinylaromatic copolymer (A-1), was 0.0% by mol (0.0 wt %), a molar fraction of the vinyl group-containing structural unit (a2) to the sum of structural units (a) and (b) was 0.00. The amount of introduction of the GPTES modifying agent was 4.7 in terms of the average number of functional groups per molecule. 50% by mol or more of the functional groups were alkoxysilyl groups, and the rest were hydroxyl groups and the like.

As a result of TGA measurement, the weight loss at 350° C. was 1.25 wt %. When a sample prepared by dissolving 0.5 g of the functional group-modified vinylaromatic copolymer (A-1) in 100 g of toluene was put into a quartz cell and the Haze (turbidity) thereof was measured using an integrating sphere type light transmittance measurement device with toluene as a reference sample, the Haze value was 0.02.

### Synthetic Example 2 Synthesis of Functional Group-Modified Vinylaromatic Copolymer (A-2)

270 ml (210.3 g) of cyclohexane and 5 g of a cyclohexane solution containing 1.73 ml (9.0 mmol) of 2,2-di(2-tetrahydrofuryl)propane were charged and 50 g of a cyclohexane solution containing 2.88 g (45.0 mmol) of n-butyllithium as pure content was added at 50° C., followed by the addition of 4.73 g of DVB-630 (22.9 mmol of a divinylbenzene (mixture of m-isomer and p-isomer) component, 13.4 mmol of an ethylvinylbenzene (mixture of m-isomer and p-isomer) component), and 27.96 g (269 mmol) of styrene, which had been cleared of impurities in advance, to initiate the polymerization. The temperature of the reaction solution increased due to the polymerization heat, reaching a maximum temperature of 81° C. After the completion of the polymerization reaction, 10.84 g (45.0 mmol) of 3-chloropropyltriethoxysilane (CPTES: the following structural formula)

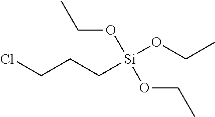

was added to the reactor as a modifying agent and subjected to a modification reaction for 30 minutes to obtain a polymer solution containing a functional group-modified vinylaromatic copolymer. After the completion of the polymerization reaction, 10.62 g (90.0 mmol) of succinic acid was added and stirred, and then filtration was performed.

CPTES was a modifying agent having an alkoxysilyl group.

The obtained polymerization solution was concentrated by devolatilization to obtain 43.09 g (yield: 99.0 wt %) of a functional group-modified vinylaromatic copolymer A-2 in solid content equivalent yield.

The analysis results of the functional group-modified vinylaromatic copolymer A-2 are shown in Table 1.

The obtained functional group-modified vinylaromatic copolymer A-2 had an Mn of 2690, an Mw of 7230, and an Mw/Mn of 2.69. GC analysis, ¹³C-NMR and ¹H-NMR analysis were performed, and the functional group-modified vinylaromatic copolymer A-2 contained 6.55% by mol (6.85 wt %) of a divinylbenzene-derived structural unit, 3.79% by mol (4.02 wt %) of an ethylvinylbenzene-derived structural unit, 76.8% by mol (64.2 wt %) of a structural unit derived from styrene, and 12.9% by mol (24.9 wt %) of a structural unit derived from 3-chloropropyltriethoxysilane. Since the crosslinked structural unit (a1) derived from the divinylaromatic compound represented by the formula (1) was 6.48% by mol (6.78 wt %), the degree of crosslinking (a1/a) was 0.99. Since the divinylbenzene-derived structural unit (a2) having a residual vinyl group, contained in the functional group-modified vinylaromatic copolymer (A-2), was 0.065% by mol (0.068 wt %), a molar fraction of the vinyl group-containing structural unit (a2) to the sum of structural units (a) and (b) was 0.00075. The amount of introduction of the CPTES modifying agent was 2.8 in terms of the average number of functional groups per molecule.

As a result of TGA measurement, the weight loss at 350° C. was 1.34 wt %. When a sample prepared by dissolving 0.5 g of the functional group-modified vinylaromatic copolymer (A-2) in 100 g of toluene was put into a quartz cell and the Haze (turbidity) thereof was measured using an integrating sphere type light transmittance measurement device with toluene as a reference sample, the Haze value was 0.03.

### Synthetic Example 3 Synthesis of Functional Group-Modified Vinylaromatic Copolymer (A-3)

120 ml (93.5 g) of ethylcyclohexane and 0.77 ml (4.0 mmol) of 2,2-di(2-tetrahydrofuryl)propane were charge and 12.5 ml of a n-hexane solution containing 1.28 g (20.0 mmol) of n-butyllithium as pure content was added at 50° C., followed by the addition of a mixture of 2.24 g of DVB-630 (10.6 mmol of a divinylbenzene (mixture of m-isomer and p-isomer) component and 6.63 mmol of an ethylvinylbenzene (mixture of m-isomer and p-isomer) component) and 12.79 g (122.8 mmol) of styrene, which had been cleared of impurities in advance, to initiate the polymerization in the first stage. The temperature of the reaction solution increased due to the polymerization heat, reaching a maximum temperature of 73° C. After the completion of the polymerization reaction, a small amount of the polymerization solution was sampled and analyzed by gas chromatograph (GC), and no unreacted monomer was observed and the polymerization conversion was confirmed to be almost 100%. GPC analysis was performed, and the copolymer on the completion of the polymerization in the first stage had an Mn of 2080, an Mw of 4390, and an Mw/Mn of 2.11. As an additional monomer, 9.54 g (140.0 mmol) of isoprene (the following structural formula)

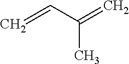

was added to the reactor, to initiate the polymerization in the second stage. After the completion of the polymerization reaction in the second stage, a small amount of the polymerization solution was sampled and subjected to GC analysis, and no unreacted monomer was observed and the polymerization conversion was confirmed to be almost 100%. GPC analysis was performed, and the copolymer on the completion of the polymerization in the second stage had an Mn of 2910, an Mw of 6630, and an Mw/Mn of 2.28. The GPC elution curve of the sample after the completion of the polymerization in the first stage and the elution curve of the sample after the completion of the polymerization in the second stage were compared, and it was thus confirmed that the GPC elution curve was shifted toward the higher molecular weight side with almost the same molecular weight distribution being kept by the addition of isoprene as an additional monomer and a substantially total amount of the active species at the terminal was converted into isoprene-derived carbanion. Then, 5.65 g (20.0 mmol) of 3-glycidoxypropyltriethoxysilane (GPTES) was added as a modifying agent and subjected to a modification reaction for 2 hours to obtain a polymer solution containing a functional group-modified vinylaromatic copolymer. After the completion of the polymerization reaction, 4.72 g (40.0 mmol) of succinic acid was added and stirred, and then filtration was performed.

The obtained polymerization solution was concentrated by devolatilization and then dissolved in ethylcyclohexane, and neither a gel, nor a microgel was confirmed to be generated. Next, in order to remove unreacted GPTES, methanol was added to such an ethylcyclohexane solution of a modified vinylaromatic copolymer to perform separation into two layers and remove a fraction soluble in methanol, and then such an ethylcyclohexane solution containing a modified vinylaromatic copolymer was concentrated by devolatilization and then dissolved in ethylcyclohexane. As a result, 29.00 g (yield: 96.0 wt %) of a functional group-modified vinylaromatic copolymer A-3 was obtained in solid content equivalent yield.

The analysis results of the functional group-modified vinylaromatic copolymer A-3 are shown in Table 2.

The obtained functional group-modified vinylaromatic copolymer A-3 had an Mn of 3470, an Mw of 9260, and an Mw/Mn of 2.67. It was confirmed by performing GC analysis, ¹³C-NMR and ¹H-NMR analysis that the modified vinylaromatic copolymer A-3 contained 3.53% by mol (4.68 wt %) of a divinylbenzene-derived structural unit, 2.21% by mol (2.93 wt %) of an ethylvinylbenzene-derived structural unit, 40.88% by mol (43.35 wt %) of a structural unit derived from styrene, 46.62% by mol (32.33 wt %) of a structural unit derived from isoprene, and 6.76% by mol (16.71 wt %) of a structural unit derived from 3-glycidoxypropyltriethoxysilane (GPTES), and 2.33 modifying agents per molecule of the modified vinylaromatic copolymer were introduced thereinto. Since the crosslinked structural unit (al) derived from the divinylaromatic compound represented by the formula (1) was 3.39% by mol (4.49 wt %), the degree of crosslinking (a1/a) was 0.96. The divinylbenzene-derived structural unit (a2) having a residual vinyl group, contained in the modified vinylaromatic copolymer (A-3), was 0.14% by mol (0.19 wt %) and a molar fraction of the vinyl group-containing structural unit (a2) to the sum of structural units (a) and (b) was 0.0015. The amount of introduction of the GPTES modifying agent was 1.9 in terms of the average number of functional groups per molecule.

As a result of thermogravimetric measurement (TGA), the weight loss at 350° C. (TGA350) was 1.17 wt %. When a sample prepared by dissolving 0.5 g of the modified vinylaromatic copolymer (A-3) in 100 g of toluene was put into a quartz cell and the Haze (turbidity) thereof was measured using an integrating sphere type light transmittance measurement device with toluene as a reference sample, the Haze value was 0.04.

### Comparative Synthetic Example 1 Synthesis of Vinylaromatic Copolymer (HA-1)

270 ml (210.3 g) of cyclohexane and 5 g of a cyclohexane solution containing 1.73 ml (9.0 mmol) of 2,2-di(2-tetrahydrofuryl)propane were charged and 50 g of a cyclohexane solution containing 2.88 g (45.0 mmol) of n-butyllithium as pure content was added at 50° C., followed by the addition of 4.73 g of DVB-630 (22.9 mmol of a divinylbenzene (mixture of m-isomer and p-isomer) component, 13.4 mmol of an ethylvinylbenzene (mixture of m-isomer and p-isomer) component), and 27.96 g (269 mmol) of styrene, which had been cleared of impurities in advance, to initiate the polymerization. The temperature of the reaction solution increased due to the polymerization heat, reaching a maximum temperature of 81° C. After the completion of the polymerization reaction, 1.44 g (45.0 mmol) of methanol was added to the reactor as a reaction terminator to stop the polymerization reaction, thereby obtaining a polymer solution containing a vinylaromatic copolymer. After the completion of the polymerization reaction, 10.62 g (90.0 mmol) of succinic acid was added and stirred, and then filtration was performed.

The obtained polymerization solution was concentrated by devolatilization to obtain 32.36 g (yield: 99.0 wt %) of a vinylaromatic copolymer HA-1 in solid content equivalent yield.

The analysis results of the vinylaromatic copolymer HA-1 are shown in Table 1.

The obtained vinylaromatic copolymer HA-1 had an Mn of 1760, an Mw of 4310, and an Mw/Mn of 2.45. GC analysis, ¹³C-NMR and ¹H-NMR analysis were performed, and the vinylaromatic copolymer HA-1 contained 7.51% by mol (9.12 wt %) of a divinylbenzene-derived structural unit, 4.35% by mol (5.35 wt %) of an ethylvinylbenzene-derived structural unit, and 88.1% by mol (85.5 wt %) of a structural unit derived from styrene. Since the crosslinked structural unit (al) derived from the divinylaromatic compound represented by the formula (1) was 7.36% by mol (8.93 wt %), the degree of crosslinking (a1/a) was 0.98. Since the divinylbenzene-derived structural unit (a2) having a residual vinyl group, contained in the vinylaromatic copolymer (HA-1), was 0.15% by mol (0.18 wt %), a molar fraction of the vinyl group-containing structural unit (a2) to the sum of structural units (a) and (b) was 0.0015.

As a result of TGA measurement, the weight loss at 350° C. was 3.12 wt %. When a sample prepared by dissolving 0.5 g of the vinylaromatic copolymer (HA-1) in 100 g of toluene was put into a quartz cell and the Haze (turbidity) thereof was measured using an integrating sphere type light transmittance measurement device with toluene as a reference sample, the Haze value was 0.08.

TABLE 1

| | | | | Comp. |
|---|---|---|---|---|
| | Synthetic | Synthetic | Synthetic | Synthetic |
| | Ex. 1 | Ex. 2 | Ex. 3 | Ex. 1 |
| Vinylaromatic copolymer | A-1 | A-2 | A-3 | HA-1 |
| Modifying agent | GPTMS | CPTES | GPTES | — |
| Mn (g/mol) | 4520 | 2690 | 3470 | 1760 |
| Mw (g/mol) | 8870 | 7230 | 9260 | 4310 |
| Mw/Mn (−) | 1.96 | 2.69 | 2.67 | 2.45 |
| Divinylbenzene content (wt %) | 6.88 | 6.85 | 4.68 | 9.12 |
| Ethylbenzene content (wt %) | 4.04 | 4.02 | 2.93 | 5.35 |
| Styrene content (wt %) | 64.5 | 64.2 | 43.4 | 85.5 |
| Isoprene content (wt %) | — | — | 32.3 | — |
| Functional group-containing | 24.5 | 24.9 | 16.7 | — |
| modification group content (wt %) | | | | |
| Average number of functional | 4.7 | 2.8 | 1.9 | — |
| groups per molecule (groups) | | | | |
| Degree of crosslinking (a1/a) (%) | 1.00 | 0.99 | 0.96 | 0.98 |
| Residual vinyl fraction (a2/(a + b)) (%) | 0.00 | 0.00075 | 0.0015 | 0.0015 |
| TGA₃₅₀ (wt %) | 1.25 | 1.34 | 1.17 | 3.12 |
| Haze (−) | 0.02 | 0.03 | 0.04 | 0.08 |

### Synthetic Example 4 Synthesis of Functional Group-Modified Vinylaromatic Copolymer (A-4)

270 ml (210.3 g) of cyclohexane and 5 g of a cyclohexane solution containing 1.73 ml (9.0 mmol) of 2,2-di(2-tetrahydrofuryl)propane were charged and 50 g of a cyclohexane solution containing 2.88 g (45.0 mmol) of n-butyllithium as pure content was added at 50° C., followed by the addition of 4.73 g of DVB-630 (22.9 mmol of a divinylbenzene (mixture of m-isomer and p-isomer) component, 13.4 mmol of an ethylvinylbenzene (mixture of m-isomer and p-isomer) component), and 27.96 g (269 mmol) of styrene, which had been cleared of impurities in advance, to initiate the polymerization. The temperature of the reaction solution increased due to the polymerization heat, reaching a maximum temperature of 81° C. After the completion of the polymerization reaction, 11.22 g (45.0 mmol) of (N, N-diethylaminomethyl) triethoxysilane (DEAMTES: the following structural formula)

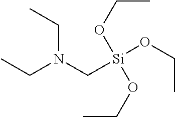 [SMILES: CCO[Si](CN(CC)CC)(OCC)OCC]

was added to the reactor as a modifying agent and subjected to a modification reaction for 30 minutes to obtain a polymer solution containing a functional group-modified vinylaromatic copolymer. After the completion of the polymerization reaction, 10.62 g (90.0 mmol) of succinic acid was added and stirred, and then filtration was performed.

DEAMTES was a modifying agent having an amino group as well as an alkoxysilyl group.

The obtained polymerization solution was concentrated by devolatilization to obtain 43.47 g (yield: 99.0 wt %) of a functional group-modified vinylaromatic copolymer A-4 in solid content equivalent yield.

The analysis results of the functional group-modified vinylaromatic copolymer A-4 are shown in Table 2.

The obtained functional group-modified vinylaromatic copolymer A-4 had an Mn of 2270, an Mw of 5690, and an Mw/Mn of 2.51. GC analysis, ¹³C-NMR and ¹H-NMR analysis were performed, and the functional group-modified vinylaromatic copolymer A-4 contained 6.55% by mol (6.79 wt %) of a divinylbenzene-derived structural unit, 3.79% by mol (3.99 wt %) of an ethylvinylbenzene-derived structural unit, 76.8% by mol (63.7 wt %) of a structural unit derived from styrene, and 12.9% by mol (25.5 wt %) of a structural unit derived from (N, N-diethylaminomethyl) triethoxysilane. Since the crosslinked structural unit (al) derived from the divinylaromatic compound represented by the formula (1) was 6.42% by mol (6.65 wt %), the degree of crosslinking (al/a) was 0.98. Since the divinylbenzene-derived structural unit (a2) having a residual vinyl group, contained in the functional group-modified vinylaromatic copolymer (A-4), was 0.13% by mol (0.13 wt %), a molar fraction of the vinyl group-containing structural unit (a2) to the sum of structural units (a) and (b) was 0.0014. The amount of introduction of the DEAMTES modifying agent was 2.4 in terms of the average number of functional groups per molecule. 50% by mol or more of the functional groups were alkoxysilyl groups, and the rest were amino groups and the like.

As a result of TGA measurement, the weight loss at 350° C. was 1.26 wt %. When a sample prepared by dissolving 0.5 g of the functional group-modified vinylaromatic copolymer (A-2) in 100 g of toluene was put into a quartz cell and the Haze (turbidity) thereof was measured using an integrating sphere type light transmittance measurement device with toluene as a reference sample, the Haze value was 0.04.

### Synthetic Example 5 Synthesis of Functional Group-Modified Vinylaromatic Copolymer (A-5)

270 ml (210.3 g) of cyclohexane and 5 g of a cyclohexane solution containing 1.73 ml (9.0 mmol) of 2,2-di(2-tetrahydrofuryl)propane were charged and 50 g of a cyclohexane solution containing 2.88 g (45.0 mmol) of n-butyllithium as pure content was added at 50° C., followed by the addition of 4.71 g of DVB-630 (the following structural formula) (22.5 mmol of a divinylbenzene (mixture of m-isomer and p-isomer) component and 13.7 mmol of an ethylvinylbenzene (mixture of m-isomer and p-isomer) component) and

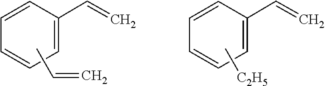

28.01 g (269 mmol) of styrene (the following structural formula),

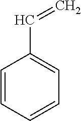

which had been cleared of impurities in advance, to initiate the polymerization. The temperature of the reaction solution increased due to the polymerization heat, reaching a maximum temperature of 81° C. After the completion of the polymerization reaction, 12.53 g (45.0 mmol) of 3-glycidoxypropyltriethoxysilane (GPTES: the following structural formula)

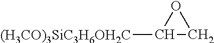

was added to the reactor as a modifying agent and subjected to a modification reaction for 30 minutes to obtain a polymer solution containing a functional group-modified vinylaromatic copolymer. After the completion of the polymerization reaction, 10.63 g (90.0 mmol) of succinic acid was added and stirred, and then filtration was performed.

The obtained polymerization solution was concentrated by devolatilization to obtain 44.43 g (yield: 98.2 wt %) of a functional group-modified vinylaromatic copolymer HA-3 in solid content equivalent yield.

The analysis results of the functional group-modified vinylaromatic copolymer A-5 are shown in Table 2.

The obtained functional group-modified vinylaromatic copolymer A-5 had an Mn of 2410, an Mw of 4240, and an Mw/Mn of 1.76. GC analysis, 13C-NMR and 1H-NMR analysis were performed, and the functional group-modified vinylaromatic copolymer A-5 contained 6.43% by mol (6.47 wt %) of a divinylbenzene-derived structural unit, 3.92% by mol (3.94 wt %) of an ethylvinylbenzene-derived structural unit, 76.8% by mol (61.9 wt %) of a structural unit derived from styrene, and 12.9% by mol (27.7 wt %) of a structural unit derived from 3-glycidoxypropyltriethoxysilane. Since the crosslinked structural unit (a1) derived from the divinylaromatic compound represented by the formula (1) was 6.30% by mol (6.34 wt %), the degree of crosslinking (a1/a) was 0.98. Since the divinylbenzene-derived structural unit (a2) having a residual vinyl group, contained in the functional group-modified vinylaromatic copolymer (A-5), was 0.13% by mol (0.13 wt %), a molar fraction of the vinyl group-containing structural unit (a2) to the sum of structural units (a) and (b) was 0.0015. The amount of introduction of the GPTES modifying agent was 2.4 in terms of the average number of functional groups per molecule. 50% by mol or more of the functional groups were alkoxysilyl groups, and the rest were hydroxyl groups and the like.

As a result of TGA measurement, the weight loss at 350° C. was 0.98 wt %. When a sample prepared by dissolving 0.5 g of the functional group-modified vinylaromatic copolymer (A-5) in 100 g of toluene was put into a quartz cell and the Haze (turbidity) thereof was measured using an integrating sphere type light transmittance measurement device with toluene as a reference sample, the Haze value was 0.03.

### Comparative Example 2 Synthesis of Functional Group-Modified Vinylaromatic Copolymer (HA-2)

270 ml (210.3 g) of cyclohexane and 5 g of a cyclohexane solution containing 1.73 ml (9.0 mmol) of 2,2-di(2-tetrahydrofuryl)propane were charged and 50 g of a cyclohexane solution containing 2.88 g (45.0 mmol) of n-butyllithium as pure content was added at 50° C., followed by the addition of 4.68 g of DVB-630 (the following structural formula) (22.5 mmol of a divinylbenzene (mixture of m-isomer and p-isomer) component and 13.4 mmol of an ethylvinylbenzene (mixture of m-isomer and p-isomer) component) and

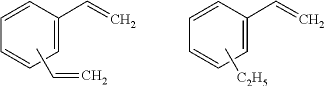

675.84 g (6,489 mmol) of styrene (the following structural formula),

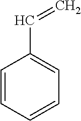

which had been cleared of impurities in advance, to initiate the polymerization. The temperature of the reaction solution increased due to the polymerization heat, reaching a maximum temperature of 81° C. After the completion of the polymerization reaction, 12.53 g (45.0 mmol) of 3-glycidoxypropyltriethoxysilane (GPTES: the following structural formula)

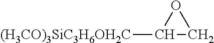

was added as a modifying agent and subjected to a modification reaction for 30 minutes to obtain a polymer solution containing a functional group-modified vinylaromatic copolymer. After the completion of the polymerization reaction, 10.63 g (90.0 mmol) of succinic acid was added and stirred, and then filtration was performed.

GPTES was a modifying agent generating a hydroxyl group by a reaction of a glycidyl group, present together with an alkoxysilyl group, mainly with carbanion as an active species.

The obtained polymerization solution was concentrated by devolatilization to obtain 686.07 g (yield: 99.0 wt %) of a functional group-modified vinylaromatic copolymer HA-2 in solid content equivalent yield.

The analysis results of the functional group-modified vinylaromatic copolymer HA-2 are shown in Table 2.

The obtained functional group-modified vinylaromatic copolymer HA-2 had an Mn of 33880, an Mw of 61660, and an Mw/Mn of 1.82. GC analysis, 13C-NMR and 1H-NMR analysis were performed, and the functional group-modified vinylaromatic copolymer HA-2 contained 0.34% by mol (0.42 wt %) of a divinylbenzene-derived structural unit, 0.20% by mol (0.25 wt %) of an ethylvinylbenzene-derived structural unit, 98.8% by mol (97.5 wt %) of a structural unit derived from styrene, and 0.68% by mol (1.81 wt %) of a structural unit derived from 3-glycidoxypropyltriethoxysilane. Since the crosslinked structural unit (a1) derived from the divinylaromatic compound represented by the formula (1) was 0.33% by mol (0.41 wt %), the degree of crosslinking (a1/a) was 0.97. Since the divinylbenzene-derived structural unit (a2) having a residual vinyl group, contained in the functional group-modified vinylaromatic copolymer (HA-2), was 0.01% by mol (0.01 wt %), a molar fraction of the vinyl group-containing structural unit (a2) to the sum of structural units (a) and (b) was 0.0001. The amount of introduction of the GPTES modifying agent was 2.2 in terms of the average number of functional groups per molecule. 50% by mol or more of the functional groups were alkoxysilyl groups, and the rest were hydroxyl groups and the like.

As a result of TGA measurement, the weight loss at 350° C. was 2.01 wt %. When a sample prepared by dissolving 0.5 g of the functional group-modified vinylaromatic copolymer (HA-2) in 100 g of toluene was put into a quartz cell and the Haze (turbidity) thereof was measured using an integrating sphere type light transmittance measurement device with toluene as a reference sample, the Haze value was 0.12.

### Comparative Example 3 Synthesis of Functional Group-Modified Vinylaromatic Copolymer (HA-3)

270 ml (210.3 g) of cyclohexane and 5 g of a cyclohexane solution containing 1.73 ml (9.0 mmol) of 2,2-di(2-tetrahydrofuryl)propane were charged and 50 g of a cyclohexane solution containing 2.88 g (45.0 mmol) of n-butyllithium as pure content was added at 50° C., followed by the addition of 28.04 g (269 mmol) of styrene (the following structural formula),

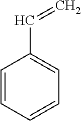

which had been cleared of impurities in advance, to initiate the polymerization. The temperature of the reaction solution increased due to the polymerization heat, reaching a maximum temperature of 76° C. Thereafter, the reaction was continued as it was for 30 minutes.

Next, a cyclohexane solution prepared by dissolving 4.73 g of DVB-630 (the following structural formula) (22.9 mmol of a divinylbenzene (mixture of m-isomer and p-isomer) component and 13.4 mmol of an ethylvinylbenzene (mixture of m-isomer and p-isomer) component), which had been cleared of impurities in advance, in 20 ml of cyclohexane was added to carry out the second step of polymerization.

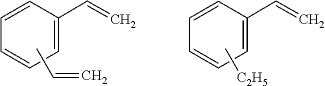

After the completion of the polymerization reaction, 12.53 g (45.0 mmol) of 3-glycidoxypropyltriethoxysilane (GPTES: the following structural formula)

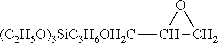

was added to the reactor as a modifying agent and subjected to a modification reaction for 30 minutes to obtain a polymer solution containing a functional group-modified vinylaromatic copolymer. After the completion of the polymerization reaction, 10.62 g (90.0 mmol) of succinic acid was added and stirred, and then filtration was performed.

The obtained polymerization solution was concentrated by devolatilization to obtain 43.88 g (yield: 97.0 wt %) of a functional group-modified vinylaromatic copolymer HA-3 in solid content equivalent yield.

The analysis results of the functional group-modified vinylaromatic copolymer HA-3 are shown in Table 2.

The obtained functional group-modified vinylaromatic copolymer HA-3 had an Mn of 1680, an Mw of 5070, and an Mw/Mn of 3.02. GC analysis, 13C-NMR and 1H-NMR analysis were performed, and the functional group-modified vinylaromatic copolymer HA-3 contained 6.43% by mol (6.47 wt %) of a divinylbenzene-derived structural unit, 3.83% by mol (3.86 wt %) of an ethylvinylbenzene-derived structural unit, 76.9% by mol (62.9 wt %) of a structural unit derived from styrene, and 12.8% by mol (27.7 wt %) of a structural unit derived from 3-glycidoxypropyltriethoxysilane. Since the crosslinked structural unit (a1) derived from the divinylaromatic compound represented by the formula (1) was 5.72% by mol (5.76 wt %), the degree of crosslinking (a1/a) was 0.89. Since the divinylbenzene-derived structural unit (a2) having a residual vinyl group, contained in the functional group-modified vinylaromatic copolymer (HA-3), was 0.71% by mol (0.71 wt %), a molar fraction of the vinyl group-containing structural unit (a2) to the sum of structural units (a) and (b) was 0.0081. The amount of introduction of the GPTES modifying agent was 1.7 in terms of the average number of functional groups per molecule. 50% by mol or more of the functional groups were alkoxysilyl groups, and the rest were hydroxyl groups and the like.

As a result of TGA measurement, the weight loss at 350° C. was 2.68 wt %. When a sample prepared by dissolving 0.5 g of the functional group-modified vinylaromatic copolymer (HA-3) in 100 g of toluene was put into a quartz cell and the Haze (turbidity) thereof was measured using an integrating sphere type light transmittance measurement device with toluene as a reference sample, the Haze value was 0.41.

TABLE 2

| | Synthetic | Synthetic | Comp. | Comp. |
|---|---|---|---|---|
| | Ex. 4 | Ex. 5 | Synthetic | Synthetic |
| | | | Ex. 2 | Ex. 3 |
| Vinylaromatic copolymer | A-4 | A-5 | HA-2 | HA-3 |
| Modifying agent | DEAMTES | GPTES | GPTES | GPTES |
| Mn (g/mol) | 2270 | 2410 | 33880 | 1680 |
| Mw (g/mol) | 5690 | 4240 | 61660 | 5070 |
| Mw/Mn (−) | 2.51 | 1.76 | 1.82 | 3.02 |
| Divinylbenzene content (wt %) | 6.79 | 6.47 | 0.42 | 6.47 |
| Ethylbenzene content (wt %) | 3.99 | 3.94 | 0.25 | 3.86 |
| Styrene content (wt %) | 63.7 | 61.9 | 98.8 | 62.9 |
| Isoprene content (wt %) | — | — | — | — |
| Functional group-containing | 25.5 | 27.7 | 1.81 | 27.7 |
| modification group content (wt %) | | | | |
| Average number of functional | 2.4 | 2.4 | 2.2 | 1.7 |
| groups per molecule (groups) | | | | |
| Degree of crosslinking | 0.98 | 0.98 | 0.97 | 0.89 |
| (a1/a) (%) | | | | |
| Residual vinyl fraction | 0.02 | 0.0015 | 0.0001 | 0.0081 |
| (a2/(a + b)) (%) | | | | |
| TGA₃₅₀ (wt %) | 1.26 | 0.98 | 2.01 | 2.68 |
| Haze (−) | 0.04 | 0.03 | 0.12 | 0.41 |

### Examples 1 to 10, and Comparative Examples 1 to 7

The copolymers A-1 to A-4 or HA-1 obtained in Synthetic Examples 1 to 3 and Comparative Synthetic Example 1 were used to prepare resin compositions. In other words, the respective copolymers A-1 to A-3 or HA-1, a curable reactive resin OPE-2St-1, a thermoplastic resin K-1, and a thermal stabilizer S-1 were blended together with a solvent toluene in the blending proportions (parts by mass) shown in Tables 3 to 6 and dissolved with stirring, followed by the addition of a reaction initiator P-1, to prepare a resin composition solution.

The respective components used herein are as follows. Curable reactive resin OPE-2St-1: polyphenylene oligomer having a vinyl group at both terminals (Mn=1160, reaction product of a 2,2′,3,3′,5,5′-hexamethylbiphenyl-4,4′-diol/2,6-dimethylphenol polycondensate and chloromethylstyrene, manufactured by Mitsubishi Gas Chemical Company, Inc.)

Curable reactive resin SA9000: polyphenylene oligomer having a methacryloyl group at both terminals obtained by modifying a terminal hydroxyl group of a polyphenylene ether with a methacryloyl group (Mw=1900, terminal functional group: 2 groups/molecule, manufactured SABIC Innovative Plastics Thermoplastic resin K-1: hydrogenated styrene butadiene block copolymer (trade name: KRATON A1536HU, manufactured by KRATON Polymers Japan Ltd.)

Thermoplastic resin K-2: polystyrene (Toyo Styrene G210C, manufactured by TOYO STYRENE Co., Ltd)

Thermal stabilizer S-1: pentaerythritol tetrakis [3-(3,5-di-tert-butyl-4-hydroxyphenyl)propionate] (trade name: ADK Stab A0-60, manufactured by ADEKA CORPORATION)

Reaction initiator P-1: α,α′-di(t-butylperoxy) diisopropylbenzene (trade name: PERBUTYL P, manufactured by NOF Corporation)

The prepared thermosetting resin composition solution was cast on a board having a polyethylene terephthalate resin (PET) sheet attached to obtain a film. The obtained film had a thickness of about 50 to 60 μm and was excellent in film formation property without stickiness or the like. This film was dried at 80° C. for 10 minutes in an air oven and thermally cured at 180° C. for 1 hour with a vacuum press molding machine to obtain a cured film having a thickness of about 50 μm.

The obtained cured film was measured and evaluated for various characteristics. The results are shown in Tables 3 to 6.

### 1) Solution Viscosity

The viscosity of a varnish solution of resin composition was measured using an E-type viscometer, at a measurement temperature of 25° C.

### 2) Tensile Strength and Tensile Breaking Elongation

Tensile strength and elongation percentage were measured using a tensile testing apparatus. The elongation percentage was measured from a chart obtained in a tensile test.

### 3) Glass Transition Temperature

A test piece used for a test of glass transition temperature was prepared out of a cured film having a thickness of 50 μm, which had been subjected to vacuum press molding, by using a vacuum press molding machine to have a width of 3.0 mm, a thickness of 50 μm, and length of 40 mm. The test piece was set in a DMA (dynamic viscoelasticity device) measuring device, and measurement was carried out through scanning at a rate of temperature rise of 3° C./min from 30° C. to 320° C. under a nitrogen stream to determine Tg from the peak top of a tan & curve.

### 4) Dielectric Constant and Loss Tangent

Dielectric constant and loss tangent at 18 GHz were measured using a cured flat-plate test piece, absolutely dried and having thereafter been kept for 24 hours in a room at a temperature of 23° C. and a humidity of 50%, utilizing a dielectric constant measuring device relying on the cavity method, manufactured by AET, Inc., in accordance with JIS C2565 standard.

After the cured flat-plate test piece was left to still stand for 500 hours at a temperature of 85° C. and a relative humidity of 85%, dielectric constant and loss tangent were measured. The dielectric constant and loss tangent after a humidity and heat resistance test were then measured.

To further check the resistance to high-temperature and thermo-oxidative degradation of the material, the cured flat-plate test piece was left to still stand at a temperature of 135° C. in an air atmosphere for 150 hours, and then dielectric constant and loss tangent were measured. The dielectric constant and loss tangent after the test of resistance to high-temperature and thermo-oxidative degradation were then measured.

### 5) Copper Foil Peel Strength

A varnish of the resin composition was cast on a 18 μm copper foil (trade name F2-WS copper foil, Rz: 2.0 μM, Ra: 0.3 μm) to form a resin-coated copper foil which was dried in an air oven at 80° C. for 10 minutes. The resin-coated copper foil was then placed on an FR-4 substrate on which the copper foil had been etched out, followed by molding and curing using a vacuum press molding machine, to obtain a laminate for evaluation. The curing conditions included raising the temperature at 3° C./min and holding a temperature of 200° C. for 60 minutes at a pressure of 3 MPa to obtain a laminate cured product as a copper clad laminate for evaluation.

A test piece having a width of 20 mm and a length of 100 mm was cut out from the laminate cured product thus obtained, and parallel incisions at a width of 10 mm were made on the copper foil surface. Thereafter, the copper foil was stripped continuously at a rate of 50 mm/min in a 90° direction with respect to the surface, the stress generated at that time was measured using a tensile tester, and the lowest value of that stress was recorded as the copper foil peel strength (in accordance with JIS C6481).

The test of copper foil peel strength after a humidity and heat resistance test involved leaving the test piece to stand for 500 hours at a temperature of 85° C. and a relative humidity of 85%, followed by a measurement made in the same manner as described above.

### 6) Moldability

An uncured film of the curable resin composition was laminated on a copper clad laminate blackened, and vacuum lamination was performed at a temperature of 110° C. and a pressure of 0.1 MPa with a vacuum laminator. Then, a bonding state of the blackened copper foil and the film was evaluated. The results of the evaluation were represented by “◯” for a favorable bonding state of the blackened copper foil and the film and “×” for a bonding state in which the blackened copper foil and the film were able to be easily peeled off.

TABLE 3

| | | | | Comp. |
|---|---|---|---|---|
| | Ex. 1 | Ex. 2 | Ex. 3 | Ex. 1 |
| Copolymer A-1 (wt %) | 2.0 | | | |
| Copolymer A-2 (wt %) | | 2.0 | | |
| Copolymer A-3 (wt %) | | | 2.0 | |
| Copolymer HA-1 (wt %) | | | | 2.0 |
| Curable reactive resin OPE-2St-1 (wt %) | 48.0 | 48.0 | 48.0 | 48.0 |
| Thermoplastic resin K-1 (wt %) | 50.0 | 50.0 | 50.0 | 50.0 |
| Thermal stabilizer S-1 (phr) | 0.2 | 0.2 | 0.2 | 0.2 |
| Reaction initiator P-1 (phr) | 0.5 | 0.5 | 0.5 | 0.5 |
| Tensile strength (N/mm²) | 37.6 | 36.6 | 35.8 | 39.6 |
| Tensile breaking elongation (%) | 67.3 | 62.3 | 72.3 | 58.6 |
| Copper foil peel strength (N/mm) | 1.13 | 1.06 | 1.11 | 0.51 |
| Glass transition temperature (° C.) | 205 | 203 | 198 | 193 |
| (TMA method) | | | | |
| Softening temperature (° C.) | >300 | >300 | >300 | >300 |
| (TMA method) | | | | |
| Dielectric constant (18 GHz), normal state | 2.62 | 2.63 | 2.64 | 2.62 |
| Loss tangent (18 GHz), normal state | 0.00142 | 0.00143 | 0.00151 | 0.00129 |
| Dielectric constant (18 GHz) after | 2.61 | 2.62 | 2.65 | 2.61 |
| humidity and heat resistance test | | | | |
| Loss tangent (18 GHz) after humidity and heat | 0.00196 | 0.00207 | 0.00211 | 0.00253 |
| resistance test | | | | |
| Dielectric constant (18 GHz) after thermo-oxidative | 2.62 | 2.59 | 2.58 | 2.63 |
| degradation resistance test | | | | |
| Loss tangent (18 GHz) after thermo-oxidative | 0.00201 | 0.00213 | 0.00236 | 0.00267 |
| degradation resistance test | | | | |
| Copper foil peel strength (kgf/cm) after | 1.07 | 0.98 | 1.01 | 0.47 |
| humidity and heat resistance test | | | | |
| Moldability | ◯ | ◯ | ◯ | X |

TABLE 4

| | | | | Comp. |
|---|---|---|---|---|
| | Ex. 4 | Ex. 5 | Ex. 6 | Ex. 2 |
| Copolymer A-1 (wt %) | 1.0 | 5.0 | | |
| Copolymer A-3 (wt %) | | | 5.0 | |
| Curable reactive resin OPE-2St-1 (wt %) | 49.0 | 45.0 | 45.0 | 50.0 |
| Thermoplastic resin K-1 (wt %) | 50.0 | 50.0 | 50.0 | 50.0 |
| Thermal stabilizer S-1 (phr) | 0.2 | 0.2 | 0.2 | 0.2 |
| Reaction initiator P-1 (phr) | 0.5 | 0.5 | 0.5 | 0.5 |
| Tensile strength (N/mm²) | 38.1 | 34.2 | 31.1 | 41.4 |
| Tensile breaking elongation (%) | 46.7 | 55.2 | 72.3 | 68.2 |
| Copper foil peel strength (N/mm) | 1.02 | 0.98 | 0.94 | 0.46 |
| Glass transition temperature (° C.) | 202 | 204 | 203 | 197 |
| (TMA method) | | | | |
| Softening temperature (° C.) | >300 | >300 | >300 | >300 |
| (TMA method) | | | | |
| Dielectric constant (18 GHz), normal state | 2.60 | 2.63 | 2.65 | 2.61 |
| Loss tangent (18 GHz), normal state | 0.00139 | 0.00159 | 0.00164 | 0.00131 |
| Dielectric constant (18 GHz) after humidity and | 2.61 | 2.62 | 2.63 | 2.62 |
| heat resistance test | | | | |
| Loss tangent (18 GHz) after humidity and heat | 0.00156 | 0.00230 | 0.00211 | 0.00141 |
| resistance test | | | | |
| Dielectric constant (18 GHz) after thermo- | 2.61 | 2.63 | 2.59 | 2.62 |
| oxidative degradation resistance test | | | | |
| Loss tangent (18 GHz) after thermo-oxidative | 0.00249 | 0.00251 | 0.00255 | 0.00261 |
| degradation resistance test | | | | |
| Copper foil peel strength (kgf/cm) after | 0.95 | 1.01 | 0.99 | 0.43 |
| humidity and heat resistance test | | | | |
| Moldability | ◯ | ◯ | ◯ | Δ |

TABLE 5

| | | Comp. | |
|---|---|---|---|
| | Ex. 7 | Ex. 3 | Ex. 8 |
| Copolymer A-2 (wt %) | 5.0 | | |
| Copolymer A-4 (wt %) | | | 2.0 |
| Curable reactive resin OPE-2St-1 (wt %) | 45.0 | 45.0 | 48.0 |
| Thermoplastic resin K-1 (wt %) | 50.0 | 50.0 | 50.0 |
| Thermoplastic resin K-2 (wt %) | | 5.0 | |
| Thermal stabilizer S-1 (phr) | 0.2 | 0.2 | 0.2 |
| Reaction initiator P-1 (phr) | 0.5 | 0.5 | 0.5 |
| Tensile strength (N/mm²) | 34.3 | 37.6 | 33.9 |
| Tensile breaking elongation (%) | 59.6 | 71.2 | 36.5 |
| Copper foil peel strength (N/mm) | 1.05 | 0.48 | 0.98 |
| Glass transition temperature (° C.) | 205 | 195 | 203 |
| (TMA method) | | | |
| Softening temperature (° C.) | >300 | >300 | >300 |
| (TMA method) | | | |
| Dielectric constant (18 GHz), normal state | 2.62 | 2.60 | 2.59 |
| Loss tangent (18 GHz), normal state | 0.00155 | 0.00129 | 0.00149 |
| Dielectric constant (18 GHz) after humidity and | 2.61 | 2.62 | 2.61 |
| heat resistance test | | | |
| Loss tangent (18 GHz) after humidity and heat | 0.00205 | 0.00138 | 0.00196 |
| resistance test | | | |
| Dielectric constant (18 GHz) after thermo- | 2.62 | 2.61 | 2.64 |
| oxidative degradation resistance test | | | |
| Loss tangent (18 GHz) after thermo-oxidative | 0.00253 | 0.00259 | 0.00266 |
| degradation resistance test | | | |
| Copper foil peel strength (kgf/cm) after humidity | 0.98 | 0.39 | 0.96 |
| and heat resistance test | | | |
| Moldability | ◯ | Δ | ◯ |

TABLE 6

| | | Comp. | | Comp. |
|---|---|---|---|---|
| | Ex. 9 | Ex. 4 | Ex. 10 | Ex. 5 |
| Copolymer A-1 (wt %) | 2.0 | | 2.0 | |
| Curable reactive resin OPE-2St-1 (wt %) | 98.0 | 100.0 | | |
| Thermoplastic resin K-1 (wt %) | | | 98.0 | 100.0 |
| Thermal stabilizer S-1 (phr) | 0.2 | 0.2 | 0.2 | 0.2 |
| Reaction initiator P-1 (phr) | 0.5 | 0.5 | | |
| Tensile strength (N/mm²) | 41.5 | 38.3 | 31.8 | 29.3 |
| Tensile breaking elongation (%) | 10.2 | 8.9 | 57.4 | 51.2 |
| Copper foil peel strength (N/mm) | 1.02 | 0.45 | 0.94 | 0.43 |
| Glass transition temperature (° C.) | 217 | 211 | 101 | 96 |
| (TMA method) | | | | |
| Softening temperature (° C.) | >300 | >300 | 104 | 99 |
| (TMA method) | | | | |
| Dielectric constant (18 GHz), normal state | 2.63 | 2.64 | 2.58 | 2.59 |
| Loss tangent (18 GHz), normal state | 0.00192 | 0.00204 | 0.00113 | 0.00116 |
| Dielectric constant (18 GHz) after humidity and | 2.64 | 2.63 | 2.60 | 2.59 |
| heat resistance test | | | | |
| Loss tangent (18 GHz) after humidity and heat | 0.00201 | 0.00224 | 0.00124 | 0.00133 |
| resistance test | | | | |
| Dielectric constant (18 GHz) after thermo- | 2.62 | 2.63 | 2.62 | 2.61 |
| oxidative degradation resistance test | | | | |
| Loss tangent (18 GHz) after thermo-oxidative | 0.00343 | 0.00457 | 0.00187 | 0.00214 |
| degradation resistance test | | | | |
| Copper foil peel strength (kgf/cm) after humidity | 0.97 | 0.38 | 0.91 | 0.41 |
| and heat resistance test | | | | |
| Moldability | ◯ | Δ | ◯ | X |

TABLE 7

| | | Comp. | Comp. | |
|---|---|---|---|---|
| | Ex. 11 | Ex. 6 | Ex. 7 | Ex. 12 |
| Copolymer A-5 (wt %) | 5.0 | | | 5.0 |
| Copolymer HA-2 (wt %) | | 5.0 | | |
| Copolymer HA-3 (wt %) | | | 5.0 | |
| Curable reactive resin OPE-2St-1 (wt %) | 45.0 | 45.0 | 45.0 | |
| Curable reactive resin SA9000 | | | | 45.0 |
| (wt %) | | | | |
| Thermoplastic resin K-1 (wt %) | 50.0 | 50.0 | 50.0 | 50.0 |
| Thermal stabilizer S-1 (phr) | 0.2 | 0.2 | 0.2 | 0.2 |
| Reaction initiator P-1 (phr) | 0.5 | 0.5 | 0.5 | 0.5 |
| Tensile strength (N/mm²) | 38.2 | 33.5 | 32.6 | 40.1 |
| Tensile breaking elongation (%) | 67.9 | 28.3 | 41.4 | 72.1 |
| Copper foil peel strength (N/mm) | 1.02 | 0.36 | 0.76 | 0.98 |
| Glass transition temperature (° C.) | 211 | 197 | 194 | 207 |
| (TMA method) | | | | |
| Softening temperature (° C.) | >300 | >300 | >300 | >300 |
| (TMA method) | | | | |
| Dielectric constant (18 GHz), normal state | 2.53 | 2.57 | 2.62 | 2.51 |
| Loss tangent (18 GHz), normal state | 0.00147 | 0.00162 | 0.00165 | 0.00135 |
| Dielectric constant (18 GHz) after humidity | 2.54 | 2.63 | 2.66 | 2.52 |
| and heat resistance test | | | | |
| Loss tangent (18 GHz) after humidity and | 0.00151 | 0.00196 | 0.00178 | 0.00139 |
| heat resistance test | | | | |
| Dielectric constant (18 GHz) after thermo- | 2.62 | 2.61 | 2.64 | 2.55 |
| oxidative degradation resistance test | | | | |
| Loss tangent (18 GHz) after thermo- | 0.00192 | 0.00259 | 0.00266 | 0.00186 |
| oxidative degradation resistance test | | | | |
| Copper foil peel strength (kgf/cm) after | 0.94 | 0.27 | 0.51 | 0.96 |
| humidity and heat resistance test | | | | |
| Moldability | ◯ | X | Δ | ◯ |

As clear from Tables 3 to 7, the resin compositions of Examples 1 to 12 using the functional group-modified vinylaromatic copolymers (A-1 to A-5) of Synthetic Examples 1 to 5 had, as compared with Comparative Examples, an alkoxysilyl group and a hydroxyl group introduced into the vinylaromatic copolymers (A-1, A-3, and A-5), an alkoxysilyl group introduced into the vinylaromatic copolymer (A-2), and an alkoxysilyl group and an amino group introduced into the vinylaromatic copolymer (A-4), and therefore were materials having improved bonding with copper foil, excellent dielectric characteristics after the humidity and heat resistance test as well as the thermo-oxidative degradation resistance test, and good moldability.

### INDUSTRIAL APPLICABILITY

The resin composition of the present invention is useful in a dielectric material, an insulating material, a heat-resistant material, a structural material, an adhesive, a sealant, paint, a coating agent, a sealing material, a print ink, a dispersant, or the like in the fields of electrical and electronic industries, spacecraft and aircraft industries, architecture and construction industries, and the like. A resin composition obtained by further compounding a curable resin can also be processed into a film, a sheet, and a prepreg, and then utilized not only in a plastic optical component, a touch panel, a flat display, a film liquid crystal device, and the like, but also in any of various optical devices including an optical waveguide and an optical lens.

1. A resin composition comprising:
(A) a functional group-modified vinylaromatic copolymer comprising a structural unit (a) derived from a divinylaromatic compound and a structural unit (b) derived from a monovinylaromatic compound, wherein 95% by mol or more of the structural unit (a) is a crosslinked structural unit (a1) represented by the following structural formula (1): 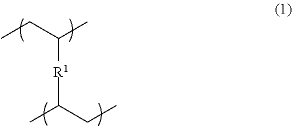
wherein R¹ represents an aromatic hydrocarbon group having 6 to 30 carbon atoms;
the functional group-modified vinylaromatic copolymer is modified by at least one functional group selected from the group consisting of an amino group, an alkoxysilyl group, and a hydroxyl group, the average number of functional groups per molecule is 1.5 or more, and a number average molecular weight Mn is 500 to 30,000; and
(B) a curable reactive resin and/or (C) a thermoplastic resin,
wherein each of components (A), (B) and (C) is blended in a proportion that satisfies the following numerical expressions (1) to (3):
$$( A ) + ( B ) + ( C ) = 100 ( wt \% ) \qquad ( 1 )$$
$$( A ) = 0.1 to 50 ( wt \% ) \qquad ( 2 )$$
$$( B ) + ( C ) = 50 to 99.9 ( wt \% ) . \qquad ( 3 )$$

2. The resin composition according to claim 1, wherein 10% by mol or more of at least one functional group selected from the group consisting of an amino group, an alkoxysilyl group, and a hydroxyl group is an alkoxysilyl group.

3. The resin composition according to claim 1, further comprising (D) a curing catalyst.

4. The resin composition according to claim 1, wherein the functional group-modified vinylaromatic copolymer (A) comprises a structural unit (c) derived from a conjugated diene compound.

5. The resin composition according to claim 1, wherein the component (B) is a thermoplastic resin comprising one or more functional groups selected from the group consisting of an epoxy group, a cyanate group, a vinyl group, an ethynyl group, an isocyanate group, and a hydroxyl group.

6. The resin composition according to claim 1, wherein the component (C) is a homopolymer or copolymer of a monomer comprising 50 to 100% by mol of one or more monomers selected from the group consisting of butadiene, isoprene, styrene, ethylstyrene, divinylbenzene, N-vinylphenylmaleimide, acrylic ester, and acrylonitrile.

7. The resin composition according to claim 1, wherein the component (C) is one or more thermoplastic resins selected from the group consisting of optionally substituted polyphenylene oxide, polyolefin having a ring structure, polysiloxane, polyester, polysulfone, polyethersulfone, polyamide, polyimide, polyamideimide, and polyetherimide.

8. The resin composition according to claim 1, further comprising (E) a flame retardant and/or (F) a filling agent.

9. A cured product obtained by curing the resin composition according to claim 1.

10. A film comprising the resin composition according to claim 1.

11. A composite material comprising the resin composition according to claim 1 and a base material, wherein a proportion of the base material contained is 5 to 90% by weight.

12. A cured composite material obtained by curing the composite material according to claim 11.

13. A laminate comprising a layer of the cured composite material according to claim 12 and a metal foil layer.

14. A resin-coated metal foil comprising a film of the resin composition according to claim 1 on one side of a metal foil.

15. A varnish for a circuit board material, obtained by dissolving the resin composition according to claim 1 in an organic solvent.
